(19) United States
(12) Patent Application Publication
(10) Pub. No.: US 2026/0188154 A1
(43) Pub. Date: Jul. 2, 2026

(54) DISPLAY DEVICE AND DISPLAY PANEL

(71) Applicant: LG DISPLAY CO., LTD., Seoul (KR)

(72) Inventors: Seunghee LEE, Paju-si (KR); Minseong YUN, Paju-si (KR)

(73) Assignee: LG DISPLAY CO., LTD., Seoul (KR)

(21) Appl. No.: 19/354,205

(22) Filed: Oct. 9, 2025

(30) Foreign Application Priority Data
Dec. 31, 2024 (KR) 10-2024-0202009

(51) Int. Cl. G09G 3/00; G09G 3/3233; H10D 86/40

(52) U.S. Cl. CPC G09G 3/006; H10D 86/441; H10D 86/451; G09G 3/3233; G09G 2300/0426; G09G 2300/0842; G09G 2300/0861; G09G 2330/12

(57) ABSTRACT

A display device can have a display panel including a display area including a subpixel and a non-display area outside of the display area, and a driving circuit configured to drive the display panel. Also, the non-display area can include a first test transistor configured to selectively detect an operation characteristic of a transistor having a different size among a plurality of subpixel transistors included in a subpixel circuit, and a second test transistor configured to selectively detect an operation characteristic of a transistor having a different position of a gate electrode among the plurality of subpixel transistors included in the subpixel circuit.

### CROSS-REFERENCE TO RELATED APPLICATION

This application claims priority to Korean Patent Application No. 10-2024-0202009, filed in the Republic of Korea on Dec. 31, 2024, the entirety of which is hereby incorporated by reference for all purposes as if fully set forth herein.

### BACKGROUND

### Field

Embodiments of the disclosure relate to a display device and a display panel and, more specifically, to a display device and a display panel including a test transistor capable of analyzing flicker characteristics of a transistor constituting a subpixel circuit.

### Description of Related Art

As information technology develops, the market for display devices, which are user-to-information connecting media, is growing. Accordingly, various display devices, such as organic light emitting display (OLED), quantum dot display (QDD), liquid crystal display (LCD), and plasma display panel (PDP), are increasingly used.

Among these display devices, the organic light emitting display device uses self-emissive organic light emitting diodes, providing advantages, such as a fast response and better contrast ratio, luminous efficiency, luminance, and viewing angle.

The organic light emitting display device can include organic light emitting diodes respectively arranged in a plurality of subpixels disposed on a display panel and cause each subpixel to emit light by controlling the driving current flowing to the organic light emitting diode to display an image by controlling the driving current flowing to the organic light emitting diode OLED through the operation of a transistor constituting the subpixel circuit.

In this situation, the display device can have different driving frequencies depending on the input image data, and can have operation characteristics of the transistor constituting the subpixel circuit depending on the driving time or environment.

In particular, since the plurality of transistors constituting the subpixel circuit can have different structures depending on their roles, it is difficult to effectively analyze the operation characteristics of various transistors with different structures through a test transistor.

For example, display devices may use a variety of transistors having different structures within their subpixel circuits. Existing technology lacks a configuration to effectively and accurately analyze the operational characteristics of these diverse transistors in an efficient manner. This testing limitation hinders manufacturing process optimization and quality control, which can lead to display issues like flicker and other performance defects.

Thus, a need exists for a display device and display panel capable of effectively and efficiently analyzing the operational characteristics of different types of transistors that have different structures within a subpixel circuit.

### SUMMARY OF THE DISCLOSURE

Embodiments of the disclosure can provide a display device and a display panel capable of effectively analyzing operation characteristics of transistors having different structures in a subpixel circuit.

Embodiments of the disclosure can provide a display device and a display panel in which a test transistor is disposed in the non-display area of the display panel to be able to selectively analyze the operation characteristics for transistors having different structures.

Embodiments of the disclosure can provide a display device and a display panel which can effectively analyze the operation characteristics of transistors having different structures through an arrangement of a plurality of upper gate electrodes and a plurality of lower gate electrodes.

Objects of embodiments of the disclosure are not limited to those set forth herein, and other unmentioned objects would be apparent to one of ordinary skill in the art from the following description.

Embodiments of the disclosure can provide a display device including a display panel including a display area where a subpixel is disposed and a non-display area where an image is not displayed outside the display area, and a driving circuit driving the display panel, in which the non-display area can include a first test transistor selectively detecting an operation characteristic of a transistor having a different size among a plurality of subpixel transistors constituting a subpixel circuit, and a second test transistor selectively detecting an operation characteristic of a transistor having a different position of a gate electrode among the plurality of subpixel transistors.

Embodiments of the disclosure can provide a display panel including a display area where a subpixel is disposed, and a non-display area where an image is not displayed outside the display area, in which the non-display area includes a first test area where a first test transistor is disposed, the first test transistor selectively detecting an operation characteristic of a transistor having a different channel layer size among a plurality of subpixel transistors constituting a subpixel circuit, and a second test area where a second test transistor is disposed, the second test transistor selectively detecting an operation characteristic of a transistor having a different gate electrode position among the plurality of subpixel transistors.

According to embodiments of the disclosure, there can be provided a display device and a display panel capable of effectively analyzing operation characteristics of transistors having different structures in a subpixel circuit.

According to embodiments of the disclosure, there can be provided a display device and a display panel in which a test transistor is disposed in the non-display area of the display panel to be able to selectively analyze the operation characteristics for transistors having different structures.

According to embodiments of the disclosure, there can be provided a display device and a display panel which can effectively analyze the operation characteristics of transistors having different structures through an arrangement of a plurality of upper gate electrodes and a plurality of lower gate electrodes.

According to embodiments of the disclosure, it is possible to achieve process optimization by disposing a test transistor to accurately reflect the operation characteristics of a transistor constituting the subpixel circuit in the non-display area of the display panel.

The effects of the disclosure are not limited to the foregoing objects, and other effects will be apparent to one of ordinary skill in the art from the following detailed description.

### BRIEF DESCRIPTION OF THE DRAWINGS

The disclosure will be more fully understood from the following detailed description and the accompanying drawings, which are provided for illustration only and are not intended to limit the disclosure. The drawings are briefly described below.

FIG. 1 is a view schematically illustrating a display device according to embodiments of the disclosure.

FIG. 2 is a system example view illustrating a display device according to embodiments of the disclosure.

FIG. 3 is a view illustrating an example of a subpixel circuit of a display device according to embodiments of the disclosure.

FIG. 4 is an example cross-sectional view illustrating a transistor constituting a subpixel circuit in a display device according to embodiments of the disclosure.

FIG. 5, including parts (a)-(c), is a view illustrating an example of a state of a carrier according to an operation of a transistor.

FIG. 6 is a view illustrating an example of a C-V characteristic of a transistor according to a frequency.

FIG. 7 is a table exemplarily illustrating a detailed structure of a transistor constituting a subpixel circuit in a display device according to embodiments of the disclosure.

FIG. 8 is an example plan view illustrating a display device according to embodiments of the disclosure.

FIG. 9 is a view illustrating an arrangement structure of a test transistor formed in a test area in a display device according to embodiments of the disclosure.

FIG. 10 is an example plan view illustrating a first test transistor in a display device according to embodiments of the disclosure.

FIG. 11 is an example cross-sectional view illustrating a first test transistor taken along line A-B of FIG. 10 in a display device according to embodiments of the disclosure.

FIG. 12 is an example plan view illustrating a second test transistor in a display device according to embodiments of the disclosure.

FIG. 13 is an example cross-sectional view illustrating a second test transistor taken along line C-D of FIG. 12 in a display device according to embodiments of the disclosure.

FIG. 14 is another example cross-sectional view illustrating a second test transistor taken along line C-D of FIG. 12 in a display device according to embodiments of the disclosure.

FIG. 15 is an example plan view illustrating a third test transistor in a display device according to embodiments of the disclosure.

FIG. 16 is an example cross-sectional view illustrating a third test transistor taken along line E-F of FIG. 15 in a display device according to embodiments of the disclosure.

FIG. 17 is another example cross-sectional view illustrating a third test transistor taken along line E-F of FIG. 15 in a display device according to embodiments of the disclosure.

FIG. 18 is an example cross-sectional view illustrating a fourth test transistor in a display device according to embodiments of the disclosure.

FIG. 19 is another cross-sectional view illustrating a fourth test transistor in a display device according to embodiments of the disclosure.

### DETAILED DESCRIPTION OF THE EMBODIMENTS

Hereinafter, some embodiments of the disclosure will be described in detail with reference to exemplary drawings. In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” can be used herein to describe elements of the disclosure. Each of these terms is not used to define essence, order, sequence, or number of elements etc., but is used merely to distinguish the corresponding element from other elements.

When it is mentioned that a first element “is connected or coupled to,” “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element can be included in at least one of two or more elements that “are connected or coupled to,” “contact or overlap,” etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may.” The features of various embodiments of the present disclosure can be partially or entirely coupled to or combined with each other and can be interlocked and operated in technically various ways, and the embodiments can be carried out independently of or in association with each other.

Hereinafter, various embodiments of the disclosure will be described in detail with reference to the accompanying drawings.

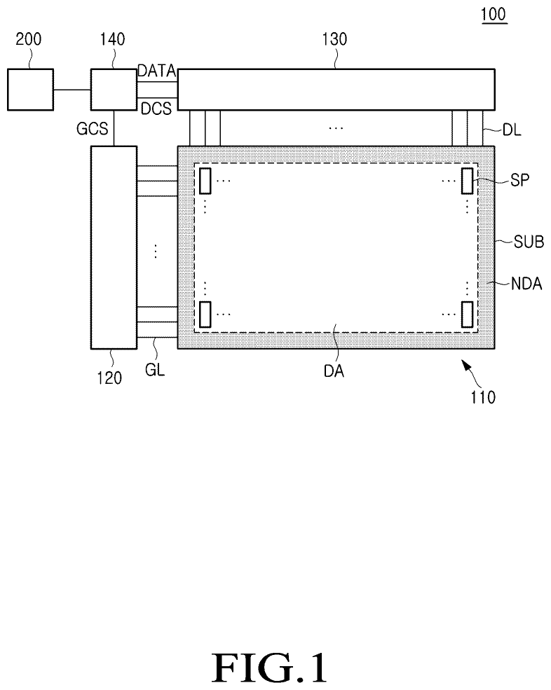

FIG. 1 is a view schematically illustrating a display device according to embodiments of the disclosure.

Referring to FIG. 1, a display device 100 according to embodiments of the disclosure can include a display panel 110 and a driving circuit for driving the display panel 110.

The display panel 110 can include a display area DA in which images are displayed and a non-display area NDA in which no image is displayed. The non-display area NDA can also be referred to as a bezel area. E.g.,

The display panel 110 can include a plurality of subpixels SP for displaying images. For example, a plurality of subpixels SP can be disposed in the display area DA. In some situations, at least one subpixel SP can be disposed in the non-display area NDA. At least one subpixel SP disposed in the non-display area NDA is also referred to as a dummy subpixel.

The display panel 110 can include a plurality of signal lines for driving a plurality of subpixels SP. For example, the plurality of signal lines can include a plurality of data lines DL and a plurality of gate lines GL. The signal lines can further include other signal lines than the plurality of data lines DL and the plurality of gate lines GL according to the structure of the subpixel SP. For example, the other signal lines can include driving voltage lines and reference voltage lines.

The plurality of data lines DL and the plurality of gate lines GL can cross each other. Each of the plurality of data lines DL can be disposed while extending in a first direction. Each of the plurality of gate lines GL can be disposed while extending in a second direction. Here, the first direction can be a column direction and the second direction can be a row direction. In the disclosure, the column direction and the row direction are relative. For example, the column direction can be a vertical direction and the row direction can be a horizontal direction. As another example, the column direction can be a horizontal direction and the row direction can be a vertical direction.

The driving circuit can include a data driving circuit 130 for driving a plurality of data lines DL and a gate driving circuit 120 for driving a plurality of gate lines GL. The driving circuit can further include a timing controller 140 for controlling the data driving circuit 130 and the gate driving circuit 120.

The data driving circuit 130 is a circuit for driving the plurality of data lines DL, and can output data signals (e.g., also referred to as data voltages) corresponding to image signals to the plurality of data lines DL. The gate driving circuit 120 is a circuit for driving the plurality of gate lines GL and can generate gate signals, and output the gate signals to the plurality of gate lines GL. The gate signal can include one or more scan signals and light emission signals.

The timing controller 140 can start a scan according to the timing implemented in each frame and can control data driving at an appropriate time according to the scan. The timing controller 140 can convert input image data input from the outside to suit the data signal format used by the data driving circuit 130 and supply the converted image data DATA to the data driving circuit 130.

The timing controller 140 can receive display driving control signals, along with input image data, from an external host system 200. For example, the display driving control signals can include a vertical synchronizing signal, a horizontal synchronizing signal, an input data enable signal, and a clock signal.

The timing controller 140 can generate the data driving control signal DCS and the gate driving control signal GCS based on display driving control signals input from the host system 200. The timing controller 140 can control the driving operation and driving timing of the data driving circuit 130 by supplying the data driving control signal DCS to the data driving circuit 130. The timing controller 140 can control the driving operation and driving timing of the gate driving circuit 120 by supplying the gate driving control signal GCS to the gate driving circuit 120.

The data driving circuit 130 can include one or more source driving integrated circuits SDIC. Each source driving integrated circuit can include a shift register, a latch circuit, a digital to analog converter (DAC), an output buffer, and the like. In some situations, each source driving integrated circuit can further include an analog to digital converter (ADC).

For example, each source driving integrated circuit can be connected with the display panel 110 by a tape automated bonding (TAB) method or connected to a bonding pad of the display panel 110 by a chip on glass (COG) or chip on panel (COP) method or can be implemented by a chip on film (COF) method and connected with the display panel 110.

The gate driving circuit 120 can output a gate signal of a turn-on level voltage or a gate signal of a turn-off level voltage according to the control of the timing controller 140. The gate driving circuit 120 can sequentially drive the plurality of gate lines GL by sequentially supplying gate signals of the turn-on level voltage to the plurality of gate lines GL.

The gate driving circuit 120 can include one or more gate driving integrated circuits GDIC.

The gate driving circuit 120 can be connected with the display panel 110 by TAB method or connected to a bonding pad of the display panel 110 by a COG or COP method or can be connected with the display panel 110 according to a COF method. Alternatively, the gate driving circuit 120 can be formed, in a gate in panel (GIP) type, in the non-display area NDA of the display panel 110. The gate driving circuit 120 can be disposed on the substrate or can be connected to the substrate. In other words, the gate driving circuit 120 that is of a GIP type can be disposed in the non-display area NDA of the substrate. The gate driving circuit 120 that is of a chip-on-glass (COG) type or chip-on-film (COF) type can be connected to the substrate.

Meanwhile, at least one of the data driving circuit 130 and the gate driving circuit 120 can be disposed in the display area DA. For example, at least one of the data driving circuit 130 and the gate driving circuit 120 can be disposed not to overlap with the subpixels SP or to overlap with all or some of the subpixels SP.

The data driving circuit 130 can be connected to one side (e.g., an upper or lower side) of the display panel 110. Depending on the driving scheme or the panel design scheme, the data driving circuit 130 can be connected with both sides (e.g., upper and lower sides) of the self-emission display panel 110, or two or more of the four sides of the self-emission display panel 110.

The gate driving circuit 120 can be connected with one side (e.g., a left or right side) of the display panel 110. Depending on the driving scheme or the panel design scheme, the gate driving circuit 120 can be connected with both sides (e.g., left and right sides) of the display panel 110, or two or more of the four sides of the display panel 110.

The timing controller 140 can be implemented as a separate component from the data driving circuit 130, or the timing controller 140 and the data driving circuit 130 can be integrated into an integrated circuit (IC). The timing controller 140 can be a controller used in typical display technology or a control device that can perform other control functions as well as the functions of the timing controller 140, or a circuit in the control device. The timing controller 140 can be implemented as various circuits or electronic components, such as an integrated circuit (IC), a field programmable gate array (FPGA), an application specific integrated circuit (ASIC), or a processor.

The timing controller 140 can be mounted on a printed circuit board or a flexible printed circuit and can be electrically connected with the data driving circuit 130 and the gate driving circuit 120 through the printed circuit board or the flexible printed circuit. The timing controller 140 can transmit/receive signals to/from the data driving circuit 130 according to one or more predetermined interfaces. The interface can include, e.g., a low voltage differential signaling (LVDS) interface, an EPI interface, and a serial peripheral interface (SP).

The display device 100 according to embodiments of the disclosure can be a self-emissive display device in which the display panel 110 emits light by itself. When the display device 100 according to the embodiments of the disclosure is a self-emissive display device, each of the plurality of subpixels SP can include a light emitting element. For example, the display device 100 according to embodiments of the disclosure can be an organic light emitting diode display in which the light emitting element is implemented as an organic light emitting diode (OLED). As another example, the display device 100 according to embodiments of the disclosure can be an inorganic light emitting display device in which the light emitting element is implemented as an inorganic material-based light emitting diode. As another example, the display device 100 according to embodiments of the disclosure can be a quantum dot display device in which the light emitting element is implemented as a quantum dot which is self-emission semiconductor crystal.

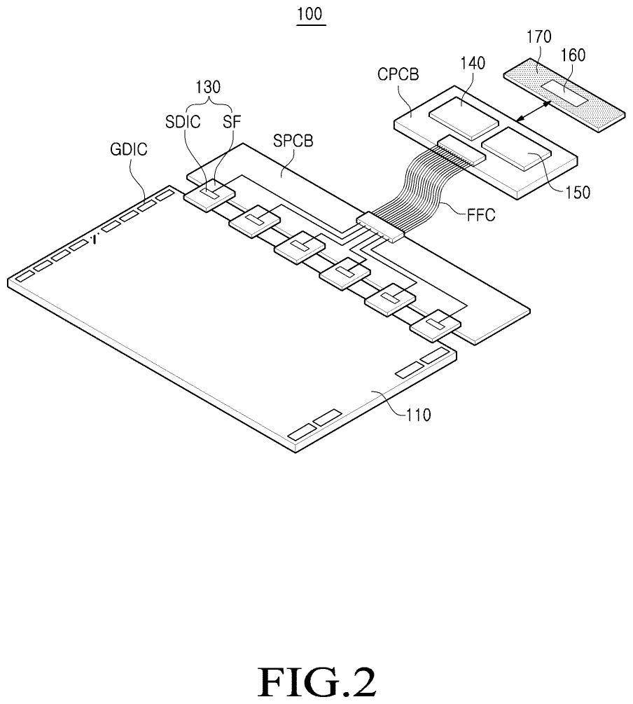

FIG. 2 is a system example view illustrating a display device according to embodiments of the disclosure.

FIG. 2 illustrates an example in which in the display device 100 according to embodiments of the disclosure, the data driving circuit 130 is implemented by a chip on film (COF) type among various types (e.g., TAB, COG, and COF), and the gate driving circuit 120 is implemented by a gate in panel (GIP) type among various types (e.g., TAB, COG, COF, and GIP).

When the gate driving circuit 120 is implemented in the GIP type, the plurality of gate driving integrated circuits GDIC included in the gate driving circuit 120 can be directly formed in the non-display area of the display panel 110. In this situation, the gate driving integrated circuits GDIC can receive various signals (e.g., a clock, a gate high signal, a gate low signal, etc.) necessary for generating scan signals through gate driving-related signal lines disposed in the non-display area.

Likewise, one or more source driving integrated circuits SDIC included in the data driving circuit 130 each can be mounted on the source film SF, and one side of the source film SF can be electrically connected with the display panel 110. Lines for electrically connecting the source driver integrated circuit SDIC and the display panel 110 can be disposed on the source film SF.

The display device 100 can include at least one source printed circuit board SPCB for circuit connection between a plurality of source driving integrated circuits SDIC and other devices and a control printed circuit board CPCB for mounting control components and various electric devices.

The other side of the source film SF where the source driving integrated circuit SDIC is mounted can be connected to at least one source printed circuit board SPCB. In other words, one side of the source film SF where the source driving integrated circuit SDIC is mounted can be electrically connected with the display panel 110, and the other side thereof can be electrically connected with the source printed circuit board SPCB.

The timing controller 140 and the power management circuit 150 can be mounted on the control printed circuit board CPCB. The timing controller 140 can control the operation of the data driving circuit 130 and the gate driving circuit 120. The power management circuit 150 can supply driving voltage or current to the display panel 110, the data driving circuit 130, and the gate driving circuit 120 and control the supplied voltage or current.

At least one source printed circuit board SPCB and control printed circuit board CPCB can be circuit-connected through at least one connection member. The connection member can include, e.g., a flexible printed circuit FPC or a flexible flat cable FFC. The at least one source printed circuit board SPCB and control printed circuit board CPCB can be integrated into a single printed circuit board.

The display device 100 can further include a set board 170 electrically connected to the control printed circuit board CPCB. In this situation, the set board 170 can also be referred to as a power board. A main power management circuit 160 for managing the overall power of the display device 100 can be present on the set board 170. The main power management circuit 160 can interwork with the power management circuit 150.

In the so-configured display device 100, the driving voltage is generated in the set board 170 and transferred to the power management circuit 150 in the control printed circuit board CPCB. The power management circuit 150 transfers a driving voltage necessary for display driving or characteristic value sensing to the source printed circuit board SPCB through the flexible printed circuit FPC or flexible flat cable FFC. The driving voltage transferred to the source printed circuit board SPCB is supplied to emit light or sense a specific subpixel SP in the display panel 110 through the source driving integrated circuit SDIC.

Each of the subpixels SP arranged in the display panel 110 in the display device 100 can include a light emitting element and a circuit element, e.g., a driving transistor, for driving the organic light emitting diode.

The type and number of circuit elements constituting each subpixel SP can be varied depending on functions to be provided and design schemes, according to embodiments.

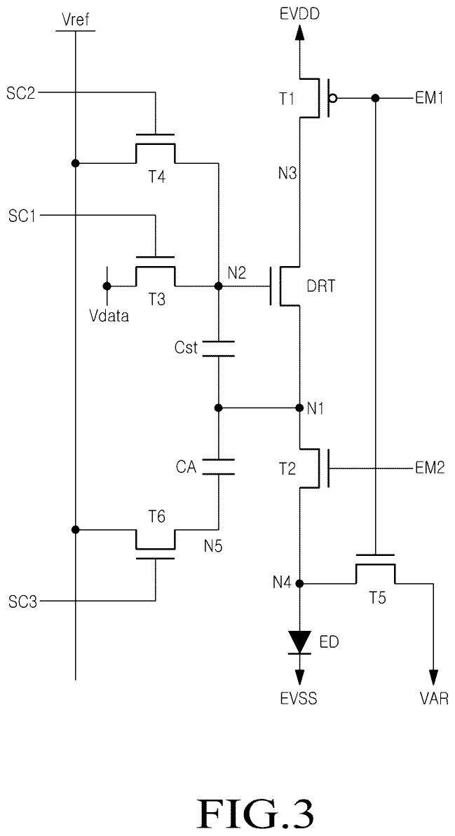

FIG. 3 is a view illustrating an example of a subpixel circuit of a display device according to embodiments of the disclosure.

Referring to FIG. 3, the subpixel circuit of the display device 100 according to embodiments of the disclosure can include a light emission element ED, a driving transistor DRT, a plurality of switching transistors T1 to T7, and a plurality of capacitors Cst and CA.

The subpixel circuit can be driven in the order of an initialization period, a sensing period, a data write period, an anode reset period, and an emission period.

The subpixel circuit can be connected to a data line DL to which a data voltage Vdata is applied and gate lines to which gate signals EM1, EM2, SC1, SC2, and SC3 are applied.

Further, the subpixel circuit can be connected to a pixel high-potential voltage line to which a pixel high-potential voltage EVDD is applied, a pixel low-potential voltage line to which a pixel low-potential voltage EVSS is applied, a reset voltage line to which a reset voltage VAR is applied, and a reference voltage line to which a reference voltage Vref is applied.

Constant voltage lines can be commonly connected to all of the subpixels SP disposed on the display panel 110. In this situation, the levels of the constant voltages EVDD, EVSS, VAR, and Vref applied to the subpixel circuit can be set in consideration of a voltage margin in the saturation area of the driving transistor DRT. For example, the level of the constant voltages EVDD, EVSS, VAR, and Vref can be set as a condition of EVDD>Vref>VAR>EVSS.

The gate signals EM1, EM2, SC1, SC2, and SC3 include a pulse that swings between the gate high voltage at the turn-on level and the gate low voltage at the turn-off level. The gate high voltage can be set to a voltage level higher than the pixel high-potential voltage EVDD, and the gate low voltage can be set to a voltage level lower than the pixel low-potential voltage EVSS.

The gate signals EM1, EM2, SC1, SC2, and SC3 include a first emission signal EM1, a second emission signal EM2, a first scan signal SC1, a second scan signal SC2, and a third scan signal SC3. The first emission signal EM1 can be interpreted as a first gate signal, the second emission signal EM2 as a second gate signal, the first scan signal SC1 as a third gate signal, the second scan signal SC2 as a fourth gate signal, and the third scan signal SC3 as interpreted as a fifth gate signal.

The driving transistor DRT generates a current according to a gate-source voltage to drive the light emitting element ED. The driving transistor DRT includes a first electrode connected to the first node N1, a gate electrode connected to the second node N2, and a second electrode connected to the third node N3.

The light emitting element ED can be implemented as an organic light emitting diode OLED. The light emitting element ED includes an anode electrode, a cathode electrode, and an organic compound layer formed between the electrodes. The anode electrode of the light emitting element ED can be connected to the fourth node N4, and the cathode electrode can be connected to a pixel low-potential voltage line to which the pixel low-potential voltage EVSS is applied.

The organic compound layer can include, but is not limited to, a hole injection layer HIL, a hole transport layer HTL, a light emission layer EML, an electron transport layer ETL, and an electron injection layer EIL.

When a voltage is applied to the anode electrode and the cathode electrode of the light emitting element ED, holes passing through the hole transport layer HTL and electrons passing through the electron transport layer ETL move to the light emitting layer EML to form excitons. In this situation, visible light is emitted from the light emitting layer EML. The light emitting element ED can be implemented in a tandem structure where a plurality of light emitting layers are stacked. The light emitting element ED having a tandem structure can enhance luminance and lifetime of subpixels.

The first capacitor Cst is connected between the first node N1 and the second node N2. The first capacitor Cst is initialized in the initialization period, and then stores the threshold voltage of the driving transistor DRT in the sensing period. The first capacitor Cst can store the data voltage Vdata compensated by the threshold voltage of the driving transistor DRT during the data write period, and then maintain the gate-source voltage of the driving transistor DRT during the anode reset period and the emission period.

The second capacitor CA is connected between the first node N1 and the seventh switching transistor T7. When the seventh switching transistor T7 is turned on, the second capacitor CA is charged with the reference voltage Vref to maintain the first node N1 as the reference voltage Vref.

The first switching transistor T1 is connected between the pixel high-potential voltage line to which the pixel high-potential voltage EVDD is applied and the third node N3 of the driving transistor DRT, and is turned on in response to the first light emission signal EM1. When the first switching transistor T1 is turned on, the pixel high-potential voltage EVDD is applied to the third node N3. The first switching transistor T1 is formed as a P-type transistor, and is turned on when the voltage of the first light emission signal EM1 is the gate low voltage.

The second switching transistor T2 is connected between the first node N1 and the fourth node N4, and is turned on in response to the second light emission signal EM2. When the second switching transistor T2 is turned on, the first node N1 is connected to the fourth node N4. The second switching transistor T2 is formed of an N-type transistor, and is turned on when the second light emission signal EM2 is a gate high voltage.

The third switching transistor T3 is connected between the data line to which the data voltage Vdata is applied and the second node N2, and is turned on in response to the first scan signal SC1. When the third switching transistor T3 is turned on, the data voltage Vdata is applied to the second node N2 of the driving transistor DRT. The third switching transistor T3 is formed of an N-type transistor, and is turned on when the first scan signal SC1 is a gate high voltage.

The fourth switching transistor T4 is connected between the reference voltage line to which the reference voltage Vref is applied and the second node N2 of the driving transistor DRT, and is turned on in response to the second scan signal SC2. When the fourth switching transistor T4 is turned on, the reference voltage Vref is applied to the second node N2. The fourth switching transistor T4 is formed as an N-type transistor, and is turned on when the voltage of the second scan signal SC2 is the gate high voltage.

The fifth switching transistor T5 is connected between the reset voltage line to which the reset voltage VAR is applied and the fourth node N4, and is turned on in response to the first light emission signal EM1. When the fifth switching transistor T5 is turned on, the reset voltage VAR is applied to the fourth node N4. The fifth switching transistor T5 is formed as an N-type transistor, and is turned on when the voltage of the first light emission signal EM1 is the gate high voltage.

The sixth switching transistor T6 is connected between the reference voltage line to which the reference voltage Vref is applied and the second capacitor CA, and is turned on in response to the third scan signal SC3. When the sixth switching transistor T6 is turned on, the reference voltage Vref is charged to the second capacitor CA. The sixth switching transistor T6 is formed as an N-type transistor, and is turned on when the voltage of the third scan signal SC3 is the gate high voltage.

The subpixel circuit can be driven in the order of an initialization period, a sensing period, a data write period, an anode reset period, and an emission period.

As described above, in the subpixel circuit according to embodiments of the disclosure, the first switching transistor T1 can be a P-type transistor, and the second switching transistor T2 to the sixth switching transistor T6 and the driving transistor DRT can be N-type transistors.

When the first switching transistor T1 is a P-type transistor, since the third node N3 can be fixed to the pixel high-potential voltage EVDD, there is an advantage that the light emitting current flowing through the light emitting element ED is not shaken by the storage capacitor Cst. Therefore, it is easy to stably supply the light emitting current. For example, this configuration can help stabilize the light emitting current and prevent it from being affected by the storage capacitor.

The P-type transistor can be a silicon transistor formed of a semiconductor such as silicon (e.g., a transistor with a polysilicon channel formed using a low-temperature process referred to as LTPS or low-temperature polysilicon).

On the other hand, the N-type transistor can be formed as an oxide transistor formed of an oxide semiconductor (e.g., a transistor with a channel formed of an oxide semiconductor such as indium, gallium, zinc oxide, IGZO, or IGZTO). Oxide transistors have characteristics of relatively lower leakage current than silicon transistors.

Accordingly, the driving transistor DRT constituting the subpixel circuit and at least some switching transistors T2 to T6 can be configured as oxide transistors. When the driving transistor DRT and the switching transistor are implemented using oxide transistors, it is possible to reduce defects in image quality such as flickers by preventing current from leaking from the driving transistor DRT. For example, the oxide transistors can prevent flicker by reducing current leakage from the driving transistor. This helps maintain stable current flow to the subpixels.

In this situation, in order to detect the flicker characteristics of the oxide transistors DRT, T2 to T6, a test transistor that can accurately detect the interface characteristics of the buffer layer through the lower gate electrode and accurately detect the interface characteristics of the gate insulating film through the upper gate electrode can be used. In other words, according to an embodiment, a specialized test transistor can be provided which is designed to precisely measure the properties of oxide transistors. The test transistor can be configured to separately analyze two components that may affect a transistor's performance and can contribute to flicker. For example, regarding the buffer layer interface, test transistor's lower gate electrode can be used to accurately detect the characteristics of the interface where the buffer layer meets the channel. Also, regarding the gate insulating film interface, the test transistor's upper gate electrode can be used to accurately detect the characteristics of the interface between the gate insulating film and the channel. In this way, by being able to test these two areas separately, the test transistor can more accurately pinpoint and measure the specific factors that may cause flicker or defects in oxide transistors.

Here, the driving transistor DRT and the switching transistors T1 to T6 constituting the subpixel circuit can be referred to as subpixel transistors.

As described above, the subpixel SP constituted of seven transistors DRT and T1 to T6 and two storage capacitors Cst and CA can be referred to as a 7T2C structure.

Here, the 7T2C structure is illustrated as an example among various structures of the subpixel SP, and the structure and number of transistors and capacitors constituting the subpixel SP can be variously changed. Meanwhile, the plurality of subpixels SP can have the same structure, or some of the plurality of subpixels SP can have a different structure.

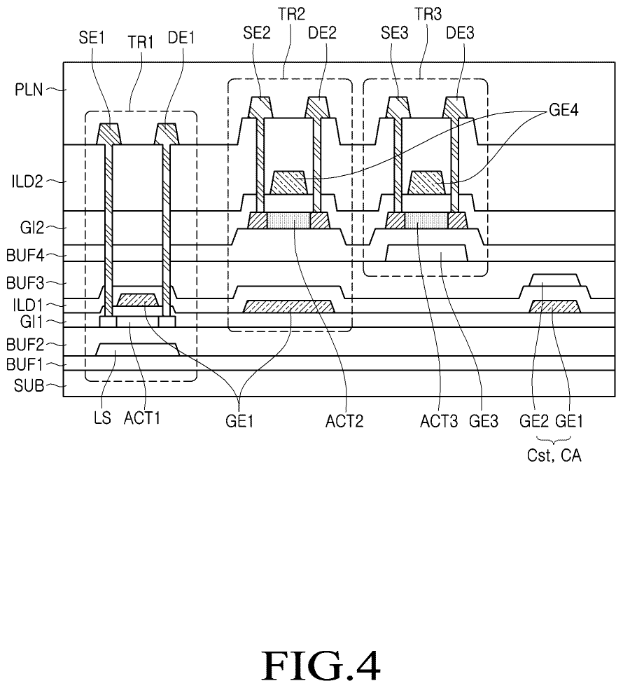

FIG. 4 is an example cross-sectional view illustrating a transistor constituting a subpixel circuit in a display device according to embodiments of the disclosure.

Referring to FIG. 4, in the display device 100 according to embodiments of the disclosure, a first buffer layer BUF1 can be formed on a substrate SUB.

A light shield layer LS for blocking light can be formed on the first buffer layer BUF1.

The second buffer layer BUF2 can be disposed to cover the light shield layer LS.

A first active layer ACT1 constituting the first transistor TR1 can be disposed on the second buffer layer BUF2.

The first transistor TR1 can include a low-temperature polysilicon transistor among the switching transistors constituting the subpixel SP. For example, the subpixel of FIG. 3 can include a first switching transistor T1.

A first gate insulation film GI1 can be disposed on the first active layer ACT1.

A first gate electrode GE1 formed of a gate material can be formed on the first gate insulation film GI1. The gate material can be an opaque conductive material having a low resistance, such as aluminum (Al), an aluminum (Al) alloy, tungsten (W), copper (Cu), nickel (Ni), chromium (Cr), molybdenum (Mo), titanium (Ti), platinum (Pt), tantalum (Ta), or the like. Alternatively, the gate material can be formed in a multilayer structure where a transparent conductive material such as indium tin oxide (ITO) and indium zinc oxide (IZO) and an opaque conductive material are stacked.

The first gate electrode GE1 can correspond to the gate electrode of the first transistor TR1 and can correspond to the lower gate electrode of the second transistor TR2 formed at the position spaced apart from the first transistor TR1. Further, the first gate electrode GE1 can correspond to one electrode forming the capacitor Cst and CA.

For example, the second transistor TR2 can be a switching transistor formed of an oxide transistor in a subpixel. In the subpixel of FIG. 3, the second transistor TR2 can correspond to the second to sixth switching transistors T2 to T6.

In this situation, the second transistor TR2 can be formed in a dual gate structure including an upper gate electrode and a lower gate electrode. In this situation, the first gate electrode GE1 can correspond to the lower gate electrode of the second transistor TR2.

The first interlayer insulation film ILD1 can be disposed to cover the first gate electrode GE1.

Meanwhile, the second gate electrode GE2 forming a capacitance with the first gate electrode GE1 can be formed on the first interlayer insulation film ILD1. The second gate electrode GE2 can be formed of the same gate material as the first gate electrode GE1, and the capacitors Cst and CA of the subpixel circuit can be formed by the first gate electrode GE1 and the second gate electrode GE2.

A third buffer layer BUF3 can be formed on the first interlayer insulation film ILD1.

A third gate electrode GE3 formed of a gate material can be formed on the third buffer layer BUF3.

The third gate electrode GE3 can correspond to the lower gate electrode of the third transistor TR3 formed at a position spaced apart from the second transistor TR2.

For example, the third transistor TR3 can be a driving transistor DRT formed of an oxide transistor in the subpixel.

In this situation, the third transistor TR3 can be formed in a dual gate structure including an upper gate electrode and a lower gate electrode. In this situation, the third gate electrode GE3 can correspond to the lower gate electrode of the third transistor TR3.

As such, the second transistor TR2 and the third transistor TR3 formed of oxide transistors can include lower gate electrodes GE1 and GE3 positioned in different layers in the vertical direction.

The fourth buffer layer BUF4 can be disposed to cover the third gate electrode GE3 on the third buffer layer BUF3.

A second active layer ACT2 constituting the second transistor TR2 and a third active layer ACT3 constituting the third transistor TR3 can be disposed on the fourth buffer layer BUF4.

The second active layer ACT2 can constitute an active layer of a switching transistor formed of an oxide transistor, and the third active layer ACT3 can constitute an active layer of a driving transistor formed of an oxide transistor.

The second gate insulation film GI2 can be disposed to cover the second active layer ACT2 and the third active layer ACT3.

Two or more fourth gate electrodes GE4 formed of a gate material can be formed on the second gate insulation film GI2.

The fourth gate electrode GE4 can correspond to the upper gate electrode of the second transistor TR2 and the upper gate electrode of the third transistor TR3.

The second interlayer insulation film ILD2 can be disposed to cover the fourth gate electrode GE4.

A plurality of source-drain electrode patterns can be disposed on the second interlayer insulation film ILD2.

The source-drain electrode pattern can be any one of molybdenum (Mo), titanium (Ti), tantalum (Ta), tungsten (W), copper (Cu), chromium (Cr), aluminum (Al), and an alloy formed of a combination thereof.

One of the plurality of source-drain electrode patterns corresponds to the first source electrode SE1 and the first drain electrode DE1 of the first transistor TR1. Further, another one of the plurality of source-drain electrode patterns corresponds to the second source electrode SE2 and the second drain electrode DE2 of the second transistor TR2. Further, yet another one of the plurality of source-drain electrode patterns corresponds to the third source electrode SE3 and the third drain electrode DE3 of the third transistor TR3.

A portion of the source-drain electrode pattern can be electrically connected to each of the second active layer ACT2 of the second transistor TR2 and the third active layer ACT3 of the third transistor TR3 through a contact hole between the second interlayer insulation film ILD2 and the second gate insulation film GI2.

Further, another portion of the source-drain electrode pattern can be electrically connected to the first active layer ACT1 of the first transistor TR1 through a contact hole of the second interlayer insulation film ILD2, the second gate insulation film GI2, the fourth buffer layer BUF4, the third buffer layer BUF3, the first interlayer insulation film ILD1, and the first gate insulation film GI1.

The planarization layer PLN can be disposed to cover the source-drain electrode pattern. The planarization layer PLN can be formed of an organic insulating material, such as an acrylic resin. In this situation, the driving transistor DRT and some switching transistors (e.g., T2 to T6) constituting the subpixel SP can have a dual gate structure including an upper gate electrode and a lower gate electrode to enhance current characteristics in a turn-on state and secure reliability.

In this situation, during the driving period of the display panel 110, a charge injection phenomenon occurs along the active layer ACT while the switching transistor connected to the driving transistor DRT is turned on and off, causing flicker due to leakage current. For example, when the switching transistor turns on and off, it can inject a small amount of electrical charge into the transistor's active layer. This injected charge can create an unwanted electrical current (e.g., a leakage current) that continues to flow even when it is not supposed to. This leakage current can cause the brightness (e.g., luminance) of the pixels to fluctuate slightly, which the human eye may perceive as a flickering effect. In other words, a flicker defect can happen when the switching of transistors create a small electrical leak that makes the screen's brightness unstable.

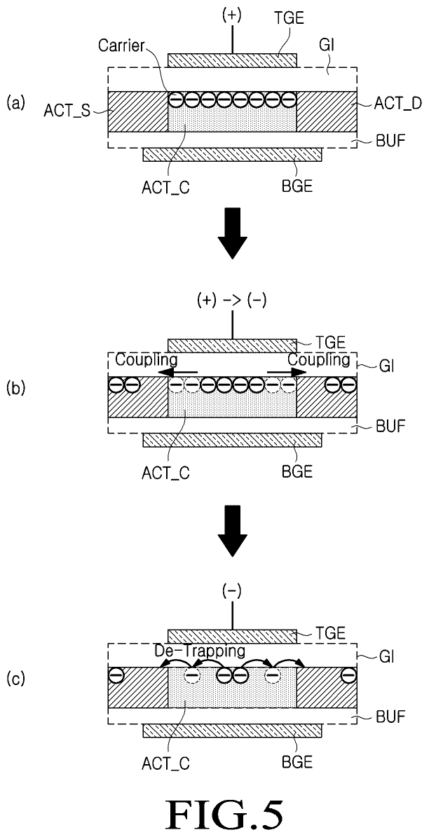

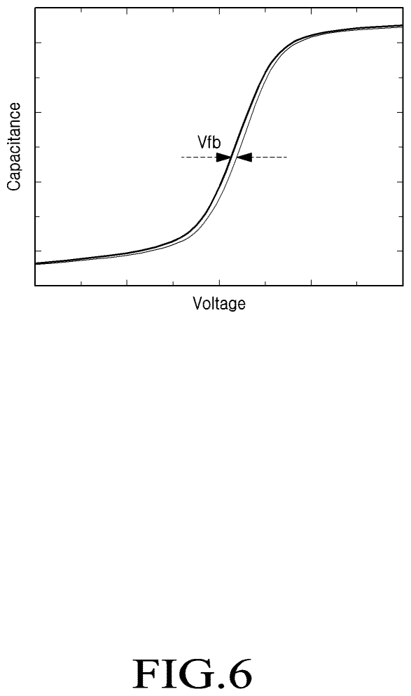

FIG. 5, including parts (a)-(c), is a view illustrating examples of a state of a carrier according to an operation of a transistor. FIG. 6 is a view illustrating an example of a C-V characteristic of a transistor according to a frequency.

Referring to FIG. 5, an active layer ACT of a transistor can include conductive semiconductor patterns ACT_S and ACT_D, electrically connected with a source electrode SE and a drain electrode DE with a channel layer ACT_C interposed therebetween, on a substrate. Further, the upper gate electrode TGE can overlap with the channel layer ACT_C with the gate insulation film GI interposed therebetween.

The channel layer ACT_C is an area doped with various kinds of impurities and has a semiconductor surface. The channel layer ACT_C can include a bulk semiconductor material (e.g., silicon) of the substrate or different semiconductor materials such as silicon germanium (SiGe), silicon carbide (SiC), or different semiconductor material layers.

In the situation of an N-type transistor, the conductive semiconductor patterns ACT_S and ACT_D electrically connected to the source electrode SE/drain electrode DE can be formed of an area doped with N-type impurities. The conductive semiconductor patterns ACT_S and ACT_D can be formed by ion implantation or diffusion. In this situation, in the process of forming the conductive semiconductor patterns ACT_S and ACT_D, a rapid thermal annealing (RTA) process can be used to activate the injected impurities.

The gate insulation film GI can include a dielectric material such as silicon oxide. The gate insulation film GI can include other suitable dielectric materials for circuit performance and manufacturing integration. For example, the gate insulation film GI can include a high-k dielectric material layer such as metal oxide, metal nitride, or metal oxynitride. The high-k dielectric material layer can include metal oxides formed by suitable methods such as metal organic chemical vapor deposition (MOCVD), physical vapor deposition (PVD), atomic layer deposition (ALD), or molecular beam epitaxy MBE, e.g., ZrO₂, Al₂O3, and HfO2.

The upper gate electrode TGE can include a metal such as aluminum, copper, tungsten, metal silicide, metal alloy, doped poly-silicon, other suitable conductive materials, or a combination thereof. The upper gate electrode TGE can include a plurality of designed conductive films such as a capping layer, a work function metal layer, a blocking layer, and a charge metal layer (e.g., aluminum or tungsten).

For example, when an N-type transistor is turned on by a high-level gate voltage applied to the upper gate electrode TGE, carriers in the channel layer ACT_C are trapped to form a channel that allows current to flow (e.g., part (a) of FIG. 5).

In this state, if the voltage applied to the upper gate electrode TGE changes from a high level to a low level, a kick-back occurs instantaneously due to the change in the gate voltage. In other words, the conductive semiconductor patterns ACT_S and ACT_D are temporarily coupled to the channel layer ACT_C, resulting in an instantaneous potential change (part (b) of FIG. 5).

After the kickback occurs, the carriers trapped in the channel layer ACT_C are released (de-trapping), charge injection where carriers are injected into the conductive semiconductor patterns ACT_S and ACT_D occurs. Due to the charge injection, a leakage current flows through the driving transistor (part (c) of FIG. 5).

As such, when the leakage current flows through the upper gate electrode TGE of the transistor, luminance fluctuations can occur, causing flicker. For example, this kickback effect during which the two conductive semiconductor patterns (ACT_S and ACT_D) may become momentarily coupled to the channel layer (ACT_C) can be a source of noise or instability in the display circuit.

This phenomenon can occur not only in transistors formed of dual gate electrodes, but also in transistors having the upper gate electrode as a single gate electrode.

In particular, when the display device 100 operates at a low-speed driving frequency, a time delay of several seconds occurs due to the leakage current caused by charge injection, worsening flicker.

In this situation, as illustrated in FIG. 6, the capacitance-voltage CV characteristic curve of the driving transistor can be shifted according to the driving frequency.

For example, the flicker characteristics of the transistor can be analyzed based on the voltage deviation Vfb of the transistor exhibiting the same capacitance at first and second driving frequencies which are different from each other.

To this end, a test transistor corresponding to the transistor constituting the subpixel circuit can be formed in the non-display area, and the operation characteristics of the transistor constituting the subpixel circuit can be analyzed through the test transistor.

However, as the number of transistors constituting the subpixel circuit of the display device 100 increases, it can be difficult to effectively measure the operation characteristics of each transistor. Further, as the structures of the transistors constituting the subpixel circuit are further diversified, it can be difficult to form test transistors of various structures in the non-display area.

The display device 100 of the disclosure can divide the structure of the transistor constituting the subpixel circuit into a plurality of groups and form a test transistor so that the operation characteristics of the transistors included in each group can be effectively analyzed. In other words, according to an embodiment, different types of transistors in the subpixel circuit can be divided into several groups based on their structure. For example, transistors with a similar design or function can be placed in the same group. Further, separate test transistors can be used for each of these groups. For example, each test transistor can be specifically tailored to analyze the operational characteristics of the transistors within its particular group.

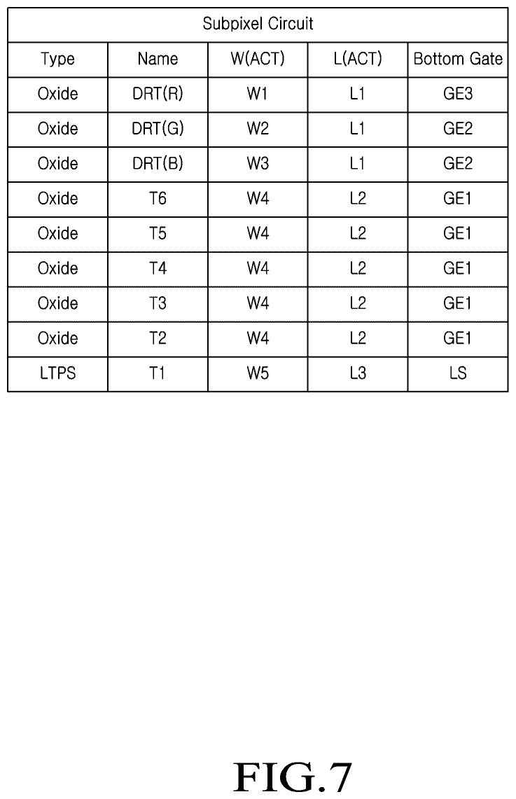

FIG. 7 is a table illustrating a detailed structure of a transistor constituting a subpixel circuit in a display device according to embodiments of the disclosure.

Referring to FIG. 7, in the display device 100 according to embodiments of the disclosure, a subpixel circuit can include a driving transistor DRT and a plurality of switching transistors T1 to T6.

In this situation, the driving transistor DRT and at least some switching transistors T2 to T6 can be formed of oxide transistors, and the remaining switching transistor T1 can be formed of a low-temperature polysilicon transistor.

In order to effectively analyze the interface characteristics of the oxide transistors DRT and T2 to T6, the display device 100 of the disclosure can adopt the structure of the oxide transistors DRT and T2 to T6 to form the test transistor in the non-display area.

First, the oxide transistors DRT and T2 to T6 constituting the subpixel circuit can be classified according to the size of the channel layer ACT.

For example, the driving transistor DRT can be formed in a different size according to the color of the light emitted by the subpixel. For example, the driving transistor DRT(R) formed in the red subpixel, the driving transistor DRT(G) formed in the green subpixel, and the driving transistor DRT(B) formed in the blue subpixel can have the same length L1 of the channel layer ACT but have different widths W1, W2, and W3.

Further, the channel layer width of the driving transistor DRT and the channel layer width W4 of the oxide switching transistors T2 to T6 can be different. Further, the channel layer length L1 of the driving transistor DRT can be different from the channel layer length L2 of the oxide switching transistors T2 to T6.

Further, when the driving transistor DRT and the oxide switching transistor T2 to T6 constituting the subpixel circuit are formed in a dual gate structure, the positions or locations of the lower gate electrodes can be different (e.g., on different layers).

For example, the oxide switching transistors T2 to T6 use the first gate electrode GE1 as the lower gate electrode, whereas the driving transistor DRT can use the second gate electrode GE2 positioned in a higher layer than the first gate electrode GE1 as the lower gate electrode

As such, when the sizes of transistors included in one subpixel circuit are different, it is difficult to form all of the test transistors respectively corresponding to the transistors in the non-display area.

Thus, the display device 100 of the disclosure enables effective analysis of the operation characteristics of transistors with various structures using the plurality of test transistors capable of selecting the size of the oxide transistor or the position of the lower gate electrode.

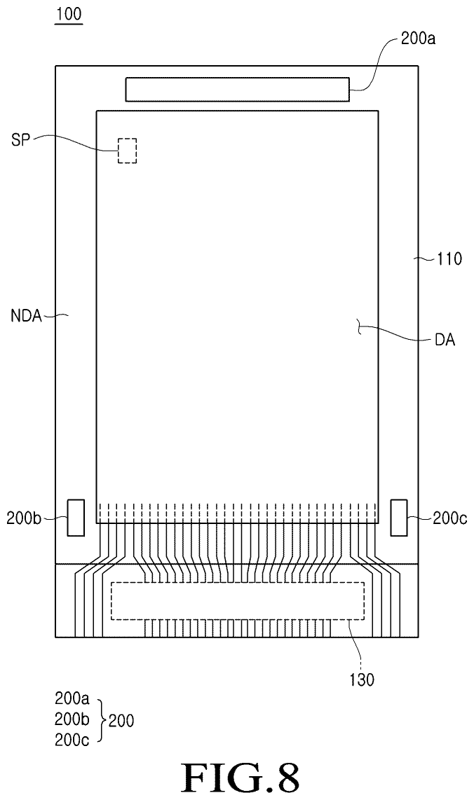

FIG. 8 is an example plan view illustrating a display device according to embodiments of the disclosure.

Referring to FIG. 8, in the display device 100 according to embodiments of the disclosure, the display panel 110 can include a display area DA where the subpixel SP emits light and a non-display area NDA where the subpixel SP does not emit light.

The display device 100 of the disclosure can form the test area 200 in the non-display area NDA formed outside the display area DA in order to analyze characteristics of the transistor positioned in the display area DA.

The test area 200 can include a plurality of test areas 200a, 200b, and 200c in order to detect operation characteristics of transistors having different structures.

For example, a first test transistor for selectively detecting operation characteristics of a plurality of oxide transistors of different sizes can be positioned in the first test area 200a.

Further, a second test transistor for detecting operation characteristics for the plurality of oxide transistors with different positions of the lower gate electrodes can be positioned in the second test area 200b.

Further, a third test transistor for detecting operation characteristics for the plurality of oxide transistors with different sizes and lower gate electrode positions can be positioned in the third test area 200c. For example, according to an embodiment, there can be three different types of test transistors, each configured to analyze a different characteristic or type of transistor.

In order to detect the operation characteristics of the transistor positioned in the display area DA, a plurality of test transistors can be connected in parallel so that capacitance of a predetermined level or higher can be accumulated. For example, the parallel connection can ensure that the combined capacitance is high enough to provide a stable and reliable reading for effective testing.

For example, the test transistors respectively formed in the test areas 200 can be connected in parallel so that capacitance of 5 pF to 20 pF can be accumulated.

The first test area 200a can be formed in the non-display area NDA at a position away from the data driving circuit 130 from the display area DA. When the first test area 200a is formed in the non-display area NDA positioned far from the data driving circuit 130, the first test area 200a can have a linear structure.

The second test area 200b and the third test area 200c can be formed in corners of the non-display area NDA adjacent to the data driving circuit 130. When the second test area 200b and the third test area 200c are positioned in the corners of the non-display area NDA, the second test area 200b and the third test area 200c can be formed in a bent structure.

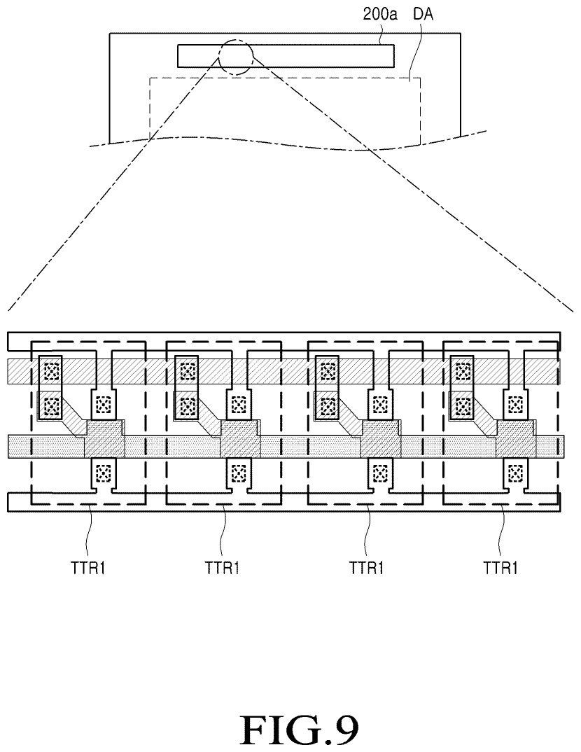

FIG. 9 is a view illustrating an arrangement structure of a test transistor formed in a test area in a display device according to embodiments of the disclosure.

Referring to FIG. 9, the display device 100 according to embodiments of the disclosure can include a test area 200 where a plurality of test transistors are connected in parallel in a partial section of the non-display area NDA corresponding to the outside of the display area DA.

For example, the first test area 200a where the first test transistor TTR1 is disposed to selectively detect operation characteristics of oxide transistors of different sizes can be formed at a position opposite to the data driving circuit 130 with respect to the display area DA.

The plurality of first test transistors TTR1 for detecting operation characteristics of oxide transistors having different sizes can be disposed in parallel in the first test area 200a. For example, 300 or less first test transistors TTR1 can be connected in parallel to the first test area 200a.

Since the test transistors formed in the test area 200 are for detecting the operation characteristics of the oxide transistor, they can be connected in parallel so that capacitance formed in the plurality of test transistors can be accumulated. For example, the plurality of test transistors can be connected to accumulate a capacitance of 5 pF to 20 pF so that operational characteristics of the oxide transistors can be detected.

Here, that the plurality of test transistors are connected in parallel means that the respective drain electrodes of the test transistors are connected to each other, and the respective source electrodes of the test transistors are connected to each other.

On the other hand, although the situation where the plurality of test transistors are connected in parallel in the horizontal direction has been described here as an example, the plurality of test transistors can be connected in parallel in the vertical direction.

As such, when the plurality of test transistors are connected in parallel, the capacitances formed in the respective test transistors can be added to be detected as the capacitance of the test transistors.

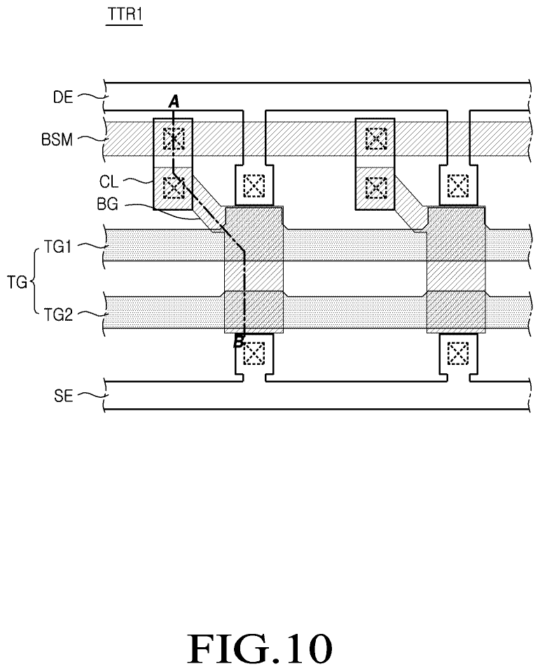

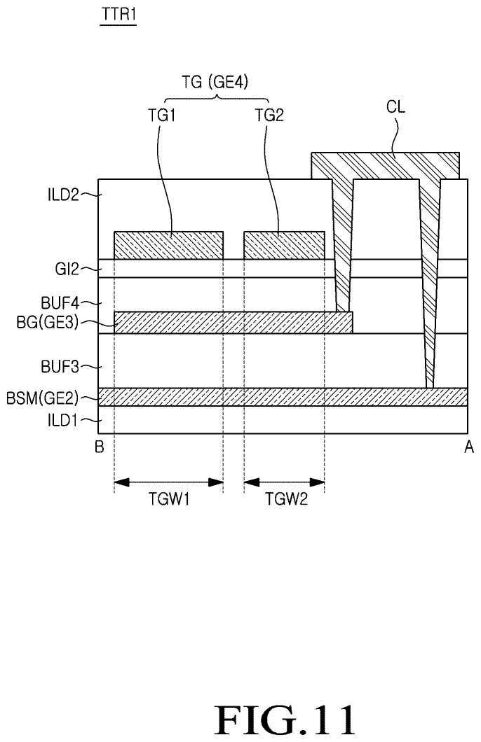

FIG. 10 is an example plan view illustrating a first test transistor in a display device according to embodiments of the disclosure. FIG. 11 is an example cross-sectional view illustrating a first test transistor taken along line A-B of FIG. 10 in a display device according to embodiments of the disclosure.

Referring to FIGS. 10 and 11, in the display device 100 according to embodiments of the disclosure, the first test transistor TTR1 can be a test transistor for selectively detecting an operation characteristic of a transistor having a different channel layer size among a plurality of transistors constituting a subpixel circuit.

The first test transistor TTR1 can be formed in the first test area 200a of the display panel 110.

The first test transistor TTR1 can include a base metal layer BSM formed on the first interlayer insulation film ILD1.

The base metal layer BSM can be formed in the same layer as the second gate electrode GE2 using a second gate metal material for forming the second gate electrode GE2 in the display area DA.

The base metal layer BSM can be electrically connected to the lower gate electrode BG of the first test transistor TTR1 to reduce resistance. Further, the base metal layer BSM can apply a voltage smaller than or equal to a threshold to detect the operation characteristics of the first test transistor TTR1.

A third buffer layer BUF3 can be formed to cover the base metal layer BSM, and a lower gate electrode BG can be formed on the third buffer layer BUF3. The lower gate electrode BG can be formed in the same layer as the third gate electrode GE3 using a third gate metal material for forming the third gate electrode GE3 in the display area DA.

A fourth buffer layer BUF4 can be stacked on the lower gate electrode BG, and a second gate insulation film GI2 can be formed on the fourth buffer layer BUF4.

Here, the third buffer layer BUF3 and the fourth buffer layer BUF4 can be referred to as insulation layers electrically insulating the lower metal and the upper metal. Therefore, a layer positioned between the upper gate electrode TG and the lower gate electrode BG can be referred to as an insulation layer.

A plurality of upper gate electrodes TG are formed on the second gate insulation film GI2. The upper gate electrode TG can include a first upper gate electrode TG1 having a first upper gate width TGW1 and a second upper gate electrode TG2 having a second upper gate width TGW2. The first upper gate width TGW1 can be different from the second upper gate width TGW2. For example, the first upper gate width TGW1 can be greater than the second upper gate width TGW2 (e.g., TGW1>TGW2), but embodiments are not limited thereto.

The first upper gate width TGW1 can correspond to the channel width of the first transistor among the plurality of transistors constituting the subpixel circuit, and the second upper gate width TGW2 can correspond to the channel width of the second transistor. For example, when the first test transistor TTR1 corresponds to a red subpixel circuit, the first upper gate width TGW1 can correspond to the channel width W1 of the red driving transistor DRT(R), and the second upper gate width TGW2 can correspond to the channel width W4 of the switching transistor.

Therefore, the first test transistor TTR1 can detect the operation characteristic by selecting the first upper gate electrode TG1 and the lower gate electrode BG. In this situation, the operation characteristic detected through the first test transistor TTR1 can correspond to the operation characteristic of the transistor having the channel width corresponding to the first upper gate width TGW1.

Further, the first test transistor TTR1 can detect the operation characteristic by selecting the second upper gate electrode TG2 and the lower gate electrode BG. In this situation, the operation characteristic detected through the first test transistor TTR1 can correspond to the operation characteristic of the transistor having the channel width corresponding to the second upper gate width TGW2.

Further, the first test transistor TTR1 can detect operation characteristics in a state in which all of the of the first upper gate electrode TG1, the second upper gate electrode TG2, and the lower gate electrode BG are selected. The operation characteristic detected through the first test transistor TTR1 will correspond to the operation characteristic of the transistor having the channel width corresponding to the sum of the first upper gate width TGW1 and the second upper gate width TGW2.

In other words, a single test transistor can be used to measure the characteristics of transistors with different channel widths by activating different gate electrodes. For example, when the first upper gate electrode (e.g., TG1) and the lower gate electrode (e.g., BG) are selected, the test transistor's characteristics can match a transistor whose channel width is equal to the width of the first upper gate (e.g., TGW1). Similarly, by selecting the second upper gate electrode (e.g., TG2) and the lower gate electrode (e.g., BG), the test transistor can measure the characteristics of a transistor whose channel width is equal to the width of the second upper gate (e.g., TGW2).

Further in this example, test transistor can also measure the characteristics of a transistor with an even wider channel, such as by activating both the first upper gate (e.g., TG1) and the second upper gate (e.g., TG2) along with the lower gate electrode (e.g., BG). In this situation, the test transistor's characteristics can correspond to a transistor with a channel width equal to the combined width of both upper gates (e.g., TGW1+TGW2).

In this way, a single test transistor to simulate and analyze the behavior of different sized transistors without needing to manufacture a separate test transistor for each size.

A second interlayer insulation film ILD2 can be formed on the upper gate electrode TG.

A contact hole can be formed so that a portion of the lower gate electrode BG is exposed by etching a portion of the second interlayer insulation film ILD2, the second gate insulation film GI2, and the fourth buffer layer BUF4, and a connection line CL contacting the lower gate electrode BG through the contact hole can be formed.

Further, a contact hole can be formed so that a portion of the base metal layer BSM is exposed by etching a portion of the second interlayer insulation film ILD2, the second gate insulation film GI2, the fourth buffer layer BUF4, and the third buffer layer BUF3. Therefore, the lower gate electrode BG and the base metal layer BSM can be electrically connected by a connection line CL formed through the contact hole.

As a result, the resistance of the lower gate electrode BG of the first test transistor TTR1 is decreased, so that the operation characteristics of the first test transistor TTR1 can be effectively detected.

As described above, the display device 100 of the disclosure has the effect of selectively detecting operation characteristics of transistors having different channel widths among the transistors constituting the subpixel circuit using the first test transistor TTR1. For example, the first test transistor TTR1 can selectively detect the performance of transistors with varying channel widths, which can provide more targeted and efficient quality control while also reducing the number of test transistors and saving space.

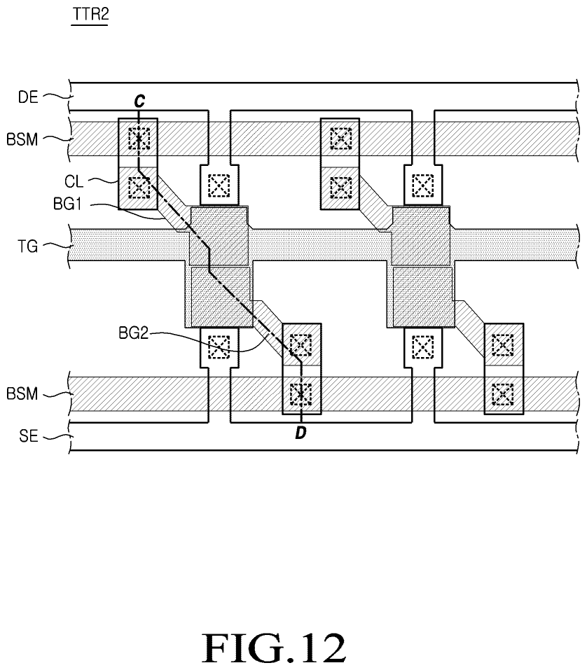

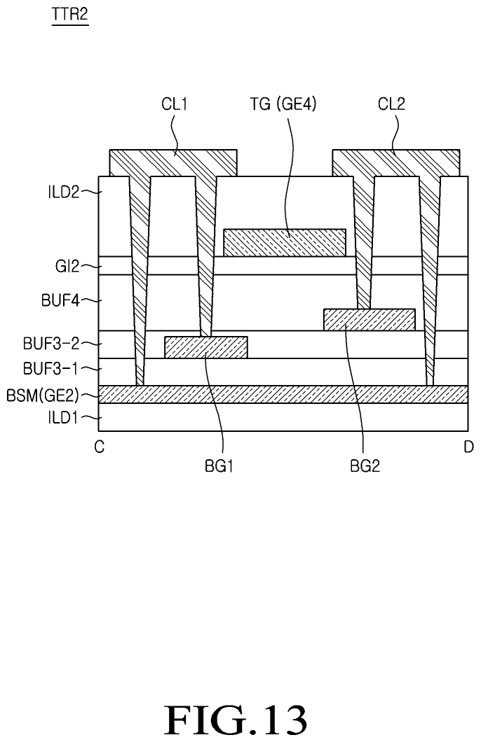

FIG. 12 is an example plan view illustrating a second test transistor in a display device according to embodiments of the disclosure. FIG. 13 is an example cross-sectional view illustrating a second test transistor taken along line C-D of FIG. 12 in a display device according to embodiments of the disclosure.

Referring to FIGS. 12 and 13, in the display device 100 according to embodiments of the disclosure, the second test transistor TTR2 can be a test transistor for selectively detecting an operation characteristic of a transistor having a different lower gate electrode position among a plurality of transistors constituting a subpixel circuit.

The second test transistor TTR2 can be formed in the second test area 200b of the display panel 110.

The second test transistor TTR2 can include a base metal layer BSM formed on the first interlayer insulation film ILD1.

The base metal layer BSM can be formed in the same layer as the second gate electrode GE2 using a second gate metal material for forming the second gate electrode GE2 in the display area DA.

The base metal layer BSM can be electrically connected to the first lower gate electrode BG1 and the second lower gate electrode BG2 of the second test transistor TTR2 to reduce the resistance. Further, the base metal layer BSM can receive a voltage smaller than or equal to a threshold to detect the operation characteristics of the second test transistor TTR2.

A 3-1th buffer layer BUF3-1 can be formed to cover the base metal layer BSM, and a first lower gate electrode BG1 can be formed on an upper portion of the 3-1th buffer layer BUF3-1. The first lower gate electrode BG1 can correspond to the lower gate electrode of the switching transistor constituting the subpixel circuit.

A 3-2th buffer layer BUF3-2 can be formed on the first lower gate electrode BG1 to cover the 3-1th buffer layer BUF3-1. A second lower gate electrode BG2 can be formed on the 3-2th buffer layer BUF3-2. The second lower gate electrode BG2 can correspond to the lower gate electrode of the driving transistor constituting the subpixel circuit.

The first lower gate electrode BG1 and the second lower gate electrode BG2 can be formed using a third gate metal material for forming the third gate electrode GE3 in the display area DA.

The first lower gate electrode BG1 and the second lower gate electrode BG2 can be formed at positions that do not overlap each other.

A fourth buffer layer BUF4 can be stacked on the second lower gate electrode BG2, and a second gate insulation film GI2 can be formed on the fourth buffer layer BUF4.

An upper gate electrode TG is formed on an upper portion of the second gate insulation film GI2.

The upper gate electrode TG can be formed using the fourth gate metal material constituting the upper gate electrode of the driving transistor and the switching transistor constituting the subpixel circuit.

In this situation, the upper gate electrode TG can be disposed to overlap with a partial area of the first lower gate electrode BG1 and a partial area of the second lower gate electrode BG2. In other words, the upper gate electrode TG can overlap with a part of the first lower gate electrode BG1 and a part of the second lower gate electrode BG2.

Therefore, the second test transistor TTR2 can detect the operation characteristic by selecting the upper gate electrode TG and the first lower gate electrode BG1. In this situation, the operation characteristic detected through the second test transistor TTR2 can correspond to the operation characteristic of the switching transistor constituting the subpixel circuit.

Further, the second test transistor TTR2 can detect the operation characteristic by selecting the upper gate electrode TG and the second lower gate electrode BG2. In this situation, the operation characteristic detected through the second test transistor TTR2 can correspond to the operation characteristic of the driving transistor constituting the subpixel circuit.

In other words, a single test transistor, e.g., the second test transistor TTR2, can be used to measure the characteristics of two different types of transistors within a subpixel circuit, such as switching transistors and driving transistors. It does this by selectively activating different lower gate electrodes. For example, when the upper gate electrode TG and the first lower gate electrode BG1 are selected, the TTR2 measures the operational characteristics of a switching transistor, and when the upper gate electrode TG and the second lower gate electrode BG2 are selected, the TTR2 measures the operational characteristics of a driving transistor. In this way, one test transistor can be used for analyzing the performance of two different kinds of transistors which can improve efficiency of the testing process.

A second interlayer insulation film ILD2 can be formed on the upper gate electrode TG.

A contact hole can be formed so that a portion of the first lower gate electrode BG1 is exposed by etching a portion of the second interlayer insulation film ILD2, the second gate insulation film GI2, the fourth buffer layer BUF4, and the 3-2th buffer layer BUF3-2, and a first connection line CL1 contacting the first lower gate electrode BG1 through the contact hole can be formed.

A contact hole can be formed so that a portion of the base metal layer BSM is exposed by etching a portion of the second interlayer insulation film ILD2, the second gate insulation film GI2, the fourth buffer layer BUF4, and the third buffer layer BUF3-1 and BUF3-2. Therefore, the first lower gate electrode BG1 and the base metal layer BSM can be electrically connected by a first connection line CL1 formed through the contact hole.

Further, a contact hole can be formed so that a portion of the second lower gate electrode BG2 is exposed by etching a portion of the second interlayer insulation film ILD2, the second gate insulation film GI2, and the fourth buffer layer BUF4, and a second connection line CL2 contacting the second lower gate electrode BG2 through the contact hole can be formed.

A contact hole can be formed so that a portion of the base metal layer BSM is exposed by etching a portion of the second interlayer insulation film ILD2, the second gate insulation film GI2, the fourth buffer layer BUF4, and the third buffer layer BUF3-1 and BUF3-2. Therefore, the second lower gate electrode BG2 and the base metal layer BSM can be electrically connected by a second connection line CL2 formed through the contact hole.

As a result, the resistance of the lower gate electrodes BG1 and BG2 of the second test transistor TTR2 is decreased, so that the operation characteristics of the second test transistor TTR2 can be effectively detected.

As described above, the display device 100 of the disclosure has the effect of selectively detecting operation characteristics of transistors having different lower gate electrode positions among the transistors constituting the subpixel circuit using the second test transistor TTR1. For example, the second test transistor TTR2 can selectively detect the performance of transistors that have different lower gate electrode positions, which can provide more targeted and efficient quality control and testing.

Meanwhile, when the first lower gate electrode BG1 and the second lower gate electrode BG2 are formed using the 3-1th buffer layer BUF3-1 and the 3-2th buffer layer BUF3-2, the mask process can be increased.

Therefore, the mask process can be decreased by forming the first lower gate electrode BG1 and the second lower gate electrode BG2 in the same layer as the gate electrode formed in the display area DA.

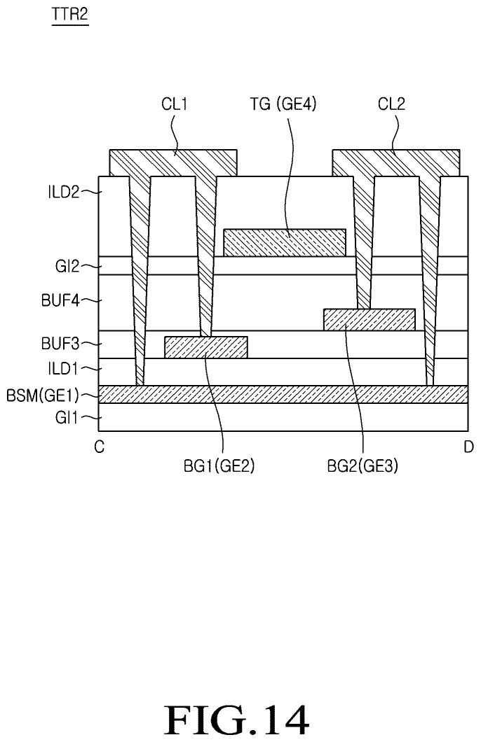

FIG. 14 is another example cross-sectional view illustrating a second test transistor taken along line C-D of FIG. 12 in a display device according to embodiments of the disclosure.

Referring to FIG. 14, in the display device 100 according to embodiments of the disclosure, the second test transistor TTR2 can be a test transistor for selectively detecting an operation characteristic of a transistor having a different lower gate electrode position among a plurality of transistors constituting a subpixel circuit.

The second test transistor TTR2 can be formed in the second test area 200b of the display panel 110.

The second test transistor TTR2 can include a base metal layer BSM formed on the first gate insulation film GI1.

The base metal layer BSM can be formed in the same layer as the first gate electrode GE1 using a first gate metal material for forming the first gate electrode GE1 in the display area DA.

The base metal layer BSM can be electrically connected to the first lower gate electrode BG1 and the second lower gate electrode BG2 of the second test transistor TTR2 to reduce the resistance. Further, the base metal layer BSM can receive a voltage smaller than or equal to a threshold to detect the operation characteristics of the second test transistor TTR2.

A first interlayer insulation film ILD1 can be formed to cover the base metal layer BSM, and a first lower gate electrode BG1 can be formed on an upper portion of the first interlayer insulation film ILD1. The first lower gate electrode BG1 can be formed in the same layer as the second gate electrode GE2 using a second gate metal material for forming the second gate electrode GE2 in the display area DA. The first lower gate electrode BG1 can correspond to the lower gate electrode of the switching transistor constituting the subpixel circuit.

A third buffer layer BUF3 can be formed on the first lower gate electrode BG1 to cover the first interlayer insulation film ILD1. A second lower gate electrode BG2 can be formed on the third buffer layer BUF3. The second lower gate electrode BG2 can be formed in the same layer as the third gate electrode GE3 using a third gate metal material for forming the third gate electrode GE3 in the display area DA. The second lower gate electrode BG2 can correspond to the lower gate electrode of the driving transistor constituting the subpixel circuit.

The first lower gate electrode BG1 and the second lower gate electrode BG2 can be formed at positions that do not overlap with each other.

A fourth buffer layer BUF4 can be stacked on the second lower gate electrode BG2, and a second gate insulation film GI2 can be formed on the fourth buffer layer BUF4.

An upper gate electrode TG is formed on an upper portion of the second gate insulation film GI2.

The upper gate electrode TG can be formed in the same layer as the fourth gate electrode GE4 using the fourth gate metal material constituting the upper gate electrode of the driving transistor and the switching transistor constituting the subpixel circuit.

In this situation, the upper gate electrode TG can be disposed to overlap with a partial area of the first lower gate electrode BG1 and a partial area of the second lower gate electrode BG2.

Therefore, the second test transistor TTR2 can detect the operation characteristic by selecting the upper gate electrode TG and the first lower gate electrode BG1. In this situation, the operation characteristic detected through the second test transistor TTR2 can correspond to the operation characteristic of the switching transistor constituting the subpixel circuit.

Further, the second test transistor TTR2 can detect the operation characteristic by selecting the upper gate electrode TG and the second lower gate electrode BG2. In this situation, the operation characteristic detected through the second test transistor TTR2 can correspond to the operation characteristic of the driving transistor constituting the subpixel circuit.

A second interlayer insulation film ILD2 can be formed on the upper gate electrode TG.

A contact hole can be formed so that a portion of the first lower gate electrode BG1 is exposed by etching a portion of the second interlayer insulation film ILD2, the second gate insulation film GI2, the fourth buffer layer BUF4, and the third buffer layer BUF3, and a first connection line CL1 contacting the first lower gate electrode BG1 through the contact hole can be formed.

A contact hole can be formed so that a portion of the base metal layer BSM is exposed by etching a portion of the second interlayer insulation film ILD2, the second gate insulation film GI2, the fourth buffer layer BUF4, the third buffer layer BUF3, and the first interlayer insulation film ILD1. Therefore, the first lower gate electrode BG1 and the base metal layer BSM can be electrically connected by a first connection line CL1 formed through the contact hole.

Further, a contact hole can be formed so that a portion of the second lower gate electrode BG2 is exposed by etching a portion of the second interlayer insulation film ILD2, the second gate insulation film GI2, and the fourth buffer layer BUF4, and a second connection line CL2 contacting the second lower gate electrode BG2 through the contact hole can be formed.

A contact hole can be formed so that a portion of the base metal layer BSM is exposed by etching a portion of the second interlayer insulation film ILD2, the second gate insulation film GI2, the fourth buffer layer BUF4, the third buffer layer BUF3, and the first interlayer insulation film ILD1. Therefore, the second lower gate electrode BG2 and the base metal layer BSM can be electrically connected by a second connection line CL2 formed through the contact hole.

As a result, the resistance of the lower gate electrodes BG1 and BG2 of the second test transistor TTR2 is decreased, so that the operation characteristics of the second test transistor TTR2 can be effectively detected.

As described above, the display device 100 of the disclosure has the effect of selectively detecting operation characteristics of transistors having different lower gate electrode positions among the transistors constituting the subpixel circuit using the second test transistor TTR1.

Further, the display device 100 of the disclosure can include a third test transistor TTR3 capable of selectively detecting the operating characteristics of transistors having different channel widths and operating characteristics of transistors having different lower gate electrode positions.

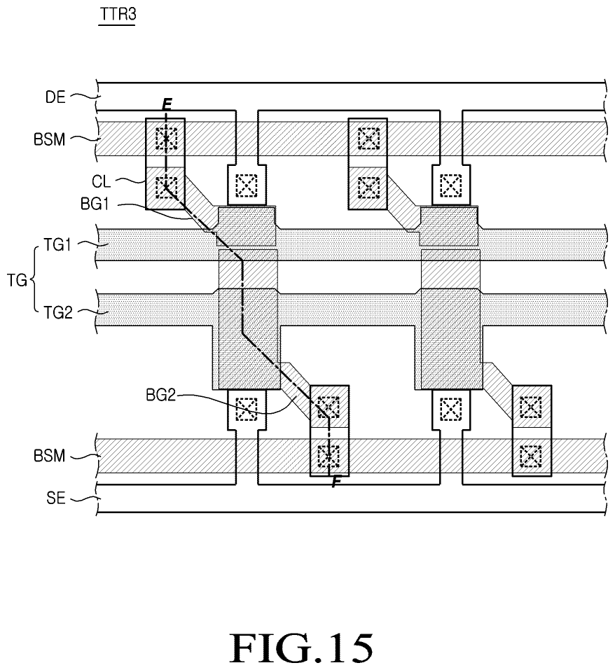

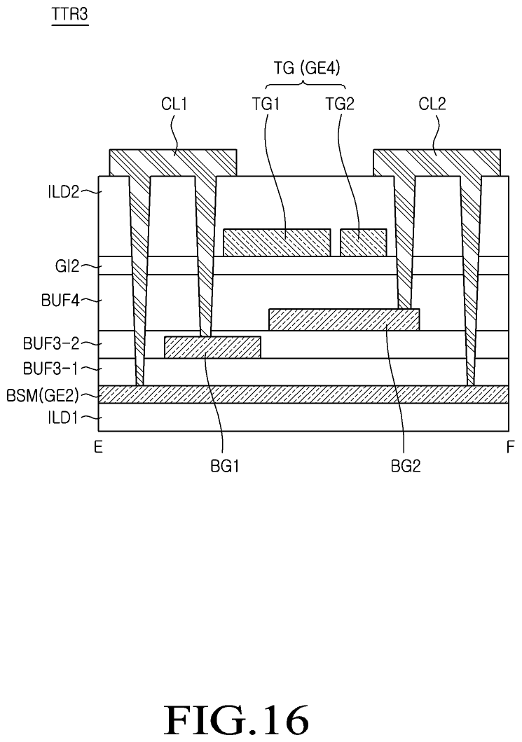

FIG. 15 is an example plan view illustrating a third test transistor in a display device according to embodiments of the disclosure. FIG. 16 is an example cross-sectional view illustrating a third test transistor taken along line E-F of FIG. 15 in a display device according to embodiments of the disclosure.

Referring to FIGS. 15 and 16, in the display device 100 according to embodiments of the disclosure, the third test transistor TTR3 can be a test transistor for selectively detecting the operation characteristics of transistors having different channel layer sizes and the operation characteristics of transistors having different lower gate electrode positions among the plurality of transistors constituting the subpixel circuit. In other words, the third test transistor TTR3 can be configured to perform the jobs of the first test transistor TTR1 and the second test transistor TTR2, which were discussed earlier. For example, the third test transistor TTR3 can analyze transistors that have different channel sizes and transistors that have lower gate electrodes located at different positions.

The third test transistor TTR3 can be formed in the third test area 200c of the display panel 110.

The third test transistor TTR3 can include a base metal layer BSM formed on the first interlayer insulation film ILD1.

The base metal layer BSM can be formed in the same layer as the second gate electrode GE2 using a second gate metal material for forming the second gate electrode GE2 in the display area DA.

The base metal layer BSM can be electrically connected to the first lower gate electrode BG1 and the second lower gate electrode BG2 of the third test transistor TTR3 to reduce the resistance. Further, the base metal layer BSM can receive a voltage smaller than or equal to a threshold to detect the operation characteristics of the third test transistor TTR3.

A 3-1th buffer layer BUF3-1 can be formed to cover the base metal layer BSM, and a first lower gate electrode BG1 can be formed on an upper portion of the 3-1th buffer layer BUF3-1.

A 3-2th buffer layer BUF3-2 can be formed on the first lower gate electrode BG1 to cover the 3-1th buffer layer BUF3-1. A second lower gate electrode BG2 can be formed on the 3-2th buffer layer BUF3-2.

The first lower gate electrode BG1 and the second lower gate electrode BG2 can be formed using a third gate metal material for forming the third gate electrode GE3 in the display area DA.

The first lower gate electrode BG1 and the second lower gate electrode BG2 can be formed at positions that do not overlap each other.

A fourth buffer layer BUF4 can be stacked on the second lower gate electrode BG2, and a second gate insulation film GI2 can be formed on the fourth buffer layer BUF4.

A plurality of upper gate electrodes TG are formed on the second gate insulation film GI2. The upper gate electrode TG can include a first upper gate electrode TG1 having a first upper gate width and a second upper gate electrode TG2 having a second upper gate width. The first upper gate width can be different from the second upper gate width.

The first upper gate electrode TG1 and the second upper gate electrode TG2 can be disposed to partially overlap with the second lower gate electrode BG2.

The first upper gate width can correspond to the channel width of the first transistor among the plurality of transistors constituting the subpixel circuit, and the second upper gate width can correspond to the channel width of the second transistor. For example, when the third test transistor TTR3 corresponds to a red subpixel circuit, the first upper gate width can correspond to the channel width W1 of the red driving transistor DRT(R), and the second upper gate width TGW2 can correspond to the channel width W4 of the switching transistor.

Therefore, the third test transistor TTR3 can detect the operation characteristic by selecting the first upper gate electrode TG1 and the first lower gate electrode BG1. In this situation, the operation characteristic detected through the third test transistor TTR3 can correspond to the operation characteristic of the transistor having the channel width corresponding to the first upper gate width.

Further, the third test transistor TTR3 can detect the operation characteristic by selecting the first upper gate electrode TG1 and the second lower gate electrode BG2. In this situation, the operation characteristics detected through the third test transistor TTR3 correspond to the operation characteristics of the transistor including the second lower gate electrode BG2 and having a channel width corresponding to the first upper gate width.

Further, the third test transistor TTR3 can detect the operation characteristic by selecting the second upper gate electrode TG2 and the second lower gate electrode BG2. In this situation, the operation characteristics detected through the third test transistor TTR3 correspond to the operation characteristics of the transistor corresponding to the second upper gate width and including the second lower gate electrode BG2.

Further, the third test transistor TTR3 can detect operation characteristics in a state in which the first upper gate electrode TG1, the second upper gate electrode TG2, and the second lower gate electrode BG2 are selected. In this situation, the operation characteristics detected through the third test transistor TTR3 correspond to the operation characteristics of the transistor including the second lower gate electrode BG2 and having a channel width corresponding to the sum of the first upper gate width and the second upper gate width.

For example, the third test transistor TTR3 can simulate or test transistors with different channel widths and transistors with different lower gate electrode position. For example, activating the first upper gate electrode TG1 can test for a transistor with a channel width of TGW1. Activating the second upper gate electrode TG2 can tests for a transistor with a channel width of TGW2. By activating both upper gate electrodes, the third test transistor TTR3 can even simulate a transistor with a combined channel width of TGW1+TGW2. Further, by combining the selection of upper gate electrodes with different lower gate electrodes, the third test transistor can also simulate transistors with varying lower gate positions.

A second interlayer insulation film ILD2 can be formed on the upper gate electrode TG.

A contact hole can be formed so that a portion of the first lower gate electrode BG1 is exposed by etching a portion of the second interlayer insulation film ILD2, the second gate insulation film GI2, the fourth buffer layer BUF4, and the 3-2th buffer layer BUF3-2, and a first connection line CL1 contacting the first lower gate electrode BG1 through the contact hole can be formed.

A contact hole can be formed so that a portion of the base metal layer BSM is exposed by etching a portion of the second interlayer insulation film ILD2, the second gate insulation film GI2, the fourth buffer layer BUF4, and the 3-2th buffer layer BUF3-2 and the 3-1th buffer layer BUF3-1. Therefore, the first lower gate electrode BG1 and the base metal layer BSM can be electrically connected by a first connection line CL1 formed through the contact hole.

Further, a contact hole can be formed so that a portion of the second lower gate electrode BG2 is exposed by etching a portion of the second interlayer insulation film ILD2, the second gate insulation film GI2, and the fourth buffer layer BUF4, and a second connection line CL2 contacting the second lower gate electrode BG2 through the contact hole can be formed.

A contact hole can be formed so that a portion of the base metal layer BSM is exposed by etching a portion of the second interlayer insulation film ILD2, the second gate insulation film GI2, the fourth buffer layer BUF4, and the 3-2th buffer layer BUF3-2 and the 3-1th buffer layer BUF3-1. Therefore, the second lower gate electrode BG2 and the base metal layer BSM can be electrically connected by a second connection line CL2 formed through the contact hole.

As a result, the resistance of the lower gate electrodes BG1 and BG2 of the third test transistor TTR3 is decreased, so that the operation characteristics of the third test transistor TTR3 can be effectively detected.

As described above, the display device 100 of the disclosure has the effect of selectively detecting operation characteristics of transistors having different channel width sizes and operation characteristics of transistors having different lower gate electrode positions using just the third test transistor TTR3. For example, the third test transistor TTR3 is a versatile tool for testing the operational characteristics of a wide variety of transistors within the subpixel circuit, e.g., those with different channel width sizes and those with different lower gate electrode positions.

Further, in the display device 100 of the disclosure, the mask process can be decreased or reduced by forming the first lower gate electrode BG1 and the second lower gate electrode BG2 of the third test transistor TTR2 in the same layer as the gate electrode formed in the display area DA.

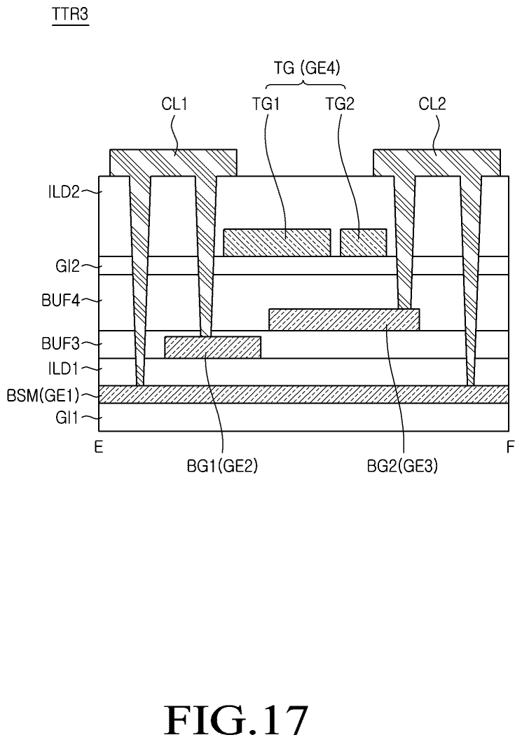

FIG. 17 is another example cross-sectional view illustrating a third test transistor taken along line E-F of FIG. 15 in a display device according to embodiments of the disclosure.

Referring to FIG. 17, in the display device 100 according to embodiments of the disclosure, the third test transistor TTR3 can be a test transistor for selectively detecting the operation characteristics of transistors having different channel layer sizes and the operation characteristics of transistors having different lower gate electrode positions among the plurality of transistors constituting the subpixel circuit.

The third test transistor TTR3 can be formed in the third test area 200c of the display panel 110.

The third test transistor TTR3 can include a base metal layer BSM formed on the first gate insulation film GI1.

The base metal layer BSM can be formed in the same layer as the first gate electrode GE1 using a first gate metal material for forming the first gate electrode GE1 in the display area DA.

The base metal layer BSM can be electrically connected to the first lower gate electrode BG1 and the second lower gate electrode BG2 of the third test transistor TTR3 to reduce the resistance. Further, the base metal layer BSM can receive a voltage smaller than or equal to a threshold to detect the operation characteristics of the third test transistor TTR3.

A first interlayer insulation film ILD1 can be formed to cover the base metal layer BSM, and a first lower gate electrode BG1 can be formed on an upper portion of the first interlayer insulation film ILD1. The first lower gate electrode BG1 can be formed in the same layer as the second gate electrode GE2 using a second gate metal material for forming the second gate electrode GE2 in the display area DA. The first lower gate electrode BG1 can correspond to the lower gate electrode of the switching transistor constituting the subpixel circuit.

A third buffer layer BUF3 can be formed on the first lower gate electrode BG1 to cover the first interlayer insulation film ILD1. A second lower gate electrode BG2 can be formed on the third buffer layer BUF3. The second lower gate electrode BG2 can correspond to the lower gate electrode of the driving transistor constituting the subpixel circuit.

The second lower gate electrode BG2 can be formed using a third gate metal material for forming the third gate electrode GE3 in the display area DA. The first lower gate electrode BG1 and the second lower gate electrode BG2 can be formed at positions that do not overlap each other.

A fourth buffer layer BUF4 can be stacked on the second lower gate electrode BG2, and a second gate insulation film GI2 can be formed on the fourth buffer layer BUF4.

A plurality of upper gate electrodes TG are formed on the second gate insulation film GI2. The upper gate electrode TG can include a first upper gate electrode TG1 having a first upper gate width and a second upper gate electrode TG2 having a second upper gate width. The first upper gate width can be different from the second upper gate width.

The first upper gate electrode TG1 and the second upper gate electrode TG2 can be disposed to partially overlay the second lower gate electrode BG2.

The first upper gate width can correspond to the channel width of the first transistor among the plurality of transistors constituting the subpixel circuit, and the second upper gate width can correspond to the channel width of the second transistor. For example, when the third test transistor TTR3 corresponds to a red subpixel circuit, the first upper gate width can correspond to the channel width W1 of the red driving transistor DRT(R), and the second upper gate width TGW2 can correspond to the channel width W4 of the switching transistor.

Therefore, the third test transistor TTR3 can detect the operation characteristic by selecting the upper gate electrode TG and the first lower gate electrode BG1. In this situation, the operation characteristic detected through the third test transistor TTR3 can correspond to the operation characteristic of the transistor having the channel width corresponding to the first upper gate width.

Further, the third test transistor TTR3 can detect the operation characteristic by selecting the first upper gate electrode TG1 and the second lower gate electrode BG2. In this situation, the operation characteristics detected through the third test transistor TTR3 correspond to the operation characteristics of the transistor including the second lower gate electrode BG2 and having a channel width corresponding to the first upper gate width.

Further, the third test transistor TTR3 can detect the operation characteristic by selecting the second upper gate electrode TG2 and the second lower gate electrode BG2. In this situation, the operation characteristics detected through the third test transistor TTR3 correspond to the operation characteristics of the transistor corresponding to the second upper gate width and including the second lower gate electrode BG2.

Further, the third test transistor TTR3 can detect operation characteristics in a state in which the first upper gate electrode TG1, the second upper gate electrode TG2, and the second lower gate electrode BG2 are selected. In this situation, the operation characteristics detected through the third test transistor TTR3 correspond to the operation characteristics of the transistor including the second lower gate electrode BG2 and having a channel width corresponding to the sum of the first upper gate width and the second upper gate width.

A second interlayer insulation film ILD2 can be formed on the upper gate electrode TG.

A contact hole can be formed so that a portion of the first lower gate electrode BG1 is exposed by etching a portion of the second interlayer insulation film ILD2, the second gate insulation film GI2, the fourth buffer layer BUF4, and the third buffer layer BUF3, and a first connection line CL1 contacting the first lower gate electrode BG1 through the contact hole can be formed.

A contact hole can be formed so that a portion of the base metal layer BSM is exposed by etching a portion of the second interlayer insulation film ILD2, the second gate insulation film GI2, the fourth buffer layer BUF4, the third buffer layer BUF3, and the first interlayer insulation film ILD1. Therefore, the first lower gate electrode BG1 and the base metal layer BSM can be electrically connected by a first connection line CL1 formed through the contact hole.

Further, a contact hole can be formed so that a portion of the second lower gate electrode BG2 is exposed by etching a portion of the second interlayer insulation film ILD2, the second gate insulation film GI2, and the fourth buffer layer BUF4, and a second connection line CL2 contacting the second lower gate electrode BG2 through the contact hole can be formed.

A contact hole can be formed so that a portion of the base metal layer BSM is exposed by etching a portion of the second interlayer insulation film ILD2, the second gate insulation film GI2, the fourth buffer layer BUF4, the third buffer layer BUF3, and the first interlayer insulation film ILD1. Therefore, the second lower gate electrode BG2 and the base metal layer BSM can be electrically connected by a second connection line CL2 formed through the contact hole.

As a result, the resistance of the lower gate electrodes BG1 and BG2 of the third test transistor TTR3 is decreased, so that the operation characteristics of the third test transistor TTR3 can be effectively detected.

As described above, the display device 100 of the disclosure has the effect of selectively detecting operation characteristics of transistors having different channel width sizes and operation characteristics of transistors having different lower gate electrode positions using the third test transistor TTR3.

Further, the display device 100 of the disclosure can include a fourth test transistor capable of selectively detecting operating characteristics of transistors having three or more different channel widths and operating characteristics of transistors having different lower gate electrode positions.

The fourth test transistor can be used to selectively detect the operating characteristics of three driving transistors disposed in different color subpixels, such as a red subpixel, a green subpixel, and a blue subpixel.

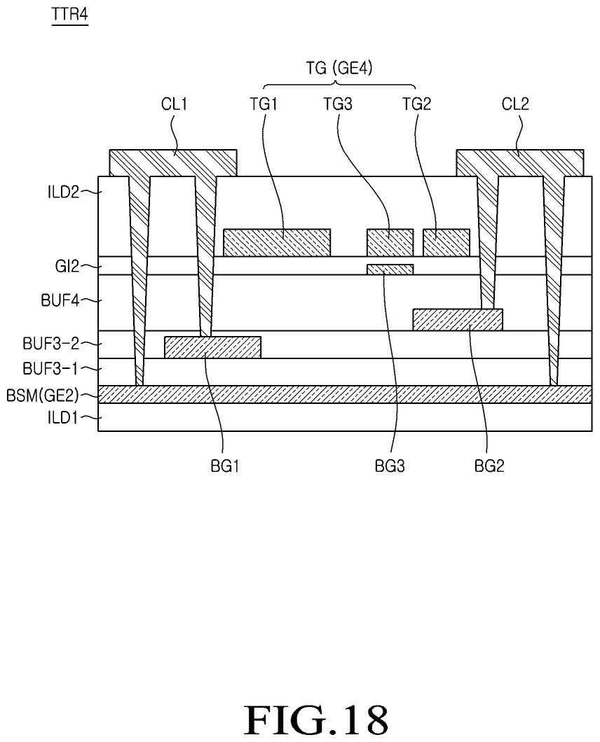

FIG. 18 is an example cross-sectional view illustrating a fourth test transistor in a display device according to embodiments of the disclosure.

Referring to FIG. 18, in the display device 100 according to embodiments of the disclosure, the fourth test transistor TTR4 can be a test transistor for selectively detecting the operation characteristics of transistors having three or more different channel widths and the operation characteristics of transistors having different lower gate electrode positions among the plurality of transistors constituting the subpixel circuit. For example, the fourth test transistor TTR4 can further include a third upper gate electrode TG3 and a third lower gate electrode BG3, according to an embodiment.

The fourth test transistor TTR4 can be formed in the third test area 200c of the display panel 110.

The fourth test transistor TTR4 can include a base metal layer BSM formed on the first interlayer insulation film ILD1.

The base metal layer BSM can be formed in the same layer as the second gate electrode GE2 using a second gate metal material for forming the second gate electrode GE2 in the display area DA.

The base metal layer BSM can be electrically connected to the first lower gate electrode BG1 and the second lower gate electrode BG2 of the fourth test transistor TTR4 to reduce the resistance. Further, the base metal layer BSM can receive a voltage smaller than or equal to a threshold to detect the operation characteristics of the fourth test transistor TTR4.

A 3-1th buffer layer BUF3-1 can be formed to cover the base metal layer BSM, and a first lower gate electrode BG1 can be formed on an upper portion of the 3-1th buffer layer BUF3-1.

A 3-2th buffer layer BUF3-2 can be formed on the first lower gate electrode BG1 to cover the 3-1th buffer layer BUF3-1. A second lower gate electrode BG2 can be formed on the 3-2th buffer layer BUF3-2.

The first lower gate electrode BG1 and the second lower gate electrode BG2 can be formed at positions that do not overlap each other.

A fourth buffer layer BUF4 can be formed on the second lower gate electrode BG2. A third lower gate electrode BG3 can be formed on the fourth buffer layer BUF4.

The first lower gate electrode BG1 to the third lower gate electrode BG3 can be formed using a third gate metal material for forming the third gate electrode GE3 in the display area DA.

A second gate insulation film GI2 can be formed on the third lower gate electrode BG3 to cover the fourth buffer layer BUF4.

A plurality of upper gate electrodes TG are formed on the second gate insulation film GI2. The upper gate electrode TG can include a first upper gate electrode TG1 having a first upper gate width, a second upper gate electrode TG2 having a second upper gate width, and a third upper gate electrode TG3 having a third upper gate width. The first upper gate width, the second upper gate width, and the third upper gate width can be different.

The first upper gate electrode TG1 can be disposed to at least partially overlap with the first lower gate electrode BG1, the second upper gate electrode TG2 can be disposed to at least partially overlap with the second lower gate electrode BG2, and the third upper gate electrode TG3 can be disposed to at least partially overlap with the third lower gate electrode BG3.

The first upper gate width can correspond to the channel width of the driving transistor constituting the red subpixel constituting the subpixel circuit, the second upper gate width can correspond to the channel width of the driving transistor constituting the green subpixel, and the third upper gate width can correspond to the channel width of the driving transistor constituting the blue subpixel.

Therefore, the fourth test transistor TTR4 can detect the operation characteristic of the driving transistor constituting the red subpixel by selecting the first upper gate electrode TG1 and the first lower gate electrode BG1.

Further, the fourth test transistor TTR4 can detect the operation characteristic of the driving transistor constituting the green subpixel by selecting the second upper gate electrode TG2 and the second lower gate electrode BG2.

Further, the fourth test transistor TTR4 can detect the operation characteristic of the driving transistor constituting the blue subpixel by selecting the third upper gate electrode TG3 and the third lower gate electrode BG3.

For example, instead of needing a separate test transistor for each color subpixel (e.g., red, green, and blue), the fourth test transistor TTR4 can use a combination of upper and lower gate electrodes to test each different color subpixel individually. For example, the fourth test transistor TTR4 can check the red subpixel's driving transistor by activating the first upper gate electrode TG1 and the first lower gate electrode BG1, can check the green subpixel's driving transistor by activating the second upper gate electrode TG2 and the second lower gate electrode BG2, and can check the blue subpixel's driving transistor by activating the third upper gate electrode TG3 and the third lower gate electrode BG3. In this way, a single test transistor can test the driving transistors of all three colors to provide a more streamlined testing process which also saves space.

A second interlayer insulation film ILD2 can be formed on the upper gate electrode TG.

A contact hole can be formed so that a portion of the first lower gate electrode BG1 is exposed by etching a portion of the second interlayer insulation film ILD2, the second gate insulation film GI2, the fourth buffer layer BUF4, and the 3-2th buffer layer BUF3-2, and a first connection line CL1 contacting the first lower gate electrode BG1 through the contact hole can be formed.

A contact hole can be formed so that a portion of the base metal layer BSM is exposed by etching a portion of the second interlayer insulation film ILD2, the second gate insulation film GI2, the fourth buffer layer BUF4, and the 3-2th buffer layer BUF3-2 and the 3-1th buffer layer BUF3-1. Therefore, the first lower gate electrode BG1 and the base metal layer BSM can be electrically connected by a first connection line CL1 formed through the contact hole.

Further, a contact hole can be formed so that a portion of the second lower gate electrode BG2 is exposed by etching a portion of the second interlayer insulation film ILD2, the second gate insulation film GI2, and the fourth buffer layer BUF4, and a second connection line CL2 contacting the second lower gate electrode BG2 through the contact hole can be formed.

A contact hole can be formed so that a portion of the base metal layer BSM is exposed by etching a portion of the second interlayer insulation film ILD2, the second gate insulation film GI2, the fourth buffer layer BUF4, and the 3-2th buffer layer BUF3-2 and the 3-1th buffer layer BUF3-1. Therefore, the second lower gate electrode BG2 and the base metal layer BSM can be electrically connected by a second connection line CL2 formed through the contact hole.

As a result, the resistance of the lower gate electrodes BG1 and BG2 of the fourth test transistor TTR4 is decreased, so that the operation characteristics of the fourth test transistor TTR4 can be effectively detected.

As described above, the display device 100 of the disclosure has the effect of selectively detecting operation characteristics of transistors having three or more different channel width sizes and operation characteristics of transistors having different lower gate electrode positions using the fourth test transistor TTR4.

Further, in the display device 100 of the disclosure, the mask process can be decreased by forming the first lower gate electrode BG1 and the second lower gate electrode BG2 of the fourth test transistor TTR4 in the same layer as the gate electrode formed in the display area DA.

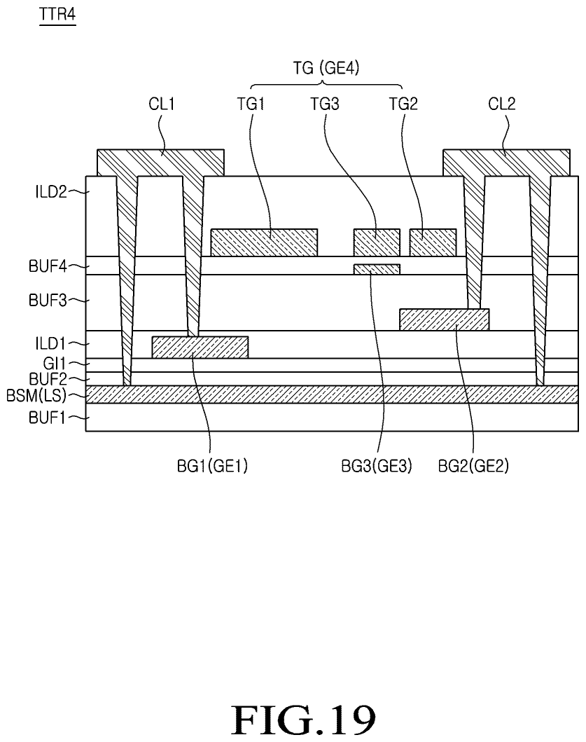

FIG. 19 is another cross-sectional view illustrating a fourth test transistor in a display device according to embodiments of the disclosure.

Referring to FIG. 19, in the display device 100 according to embodiments of the disclosure, the fourth test transistor TTR4 can be a test transistor for selectively detecting the operation characteristics of transistors having three or more different channel widths and the operation characteristics of transistors having different lower gate electrode positions among the plurality of transistors constituting the subpixel circuit.

The fourth test transistor TTR4 can be formed in the third test area 200c of the display panel 110.

The fourth test transistor TTR4 can include a base metal layer BSM formed on the first buffer layer BUF1.

The base metal layer BSM can be formed in the same layer as the light shield layer LS using a gate metal material for forming the light shield layer LS in the display area DA.

The base metal layer BSM can be electrically connected to the first lower gate electrode BG1 and the second lower gate electrode BG2 of the fourth test transistor TTR4 to reduce the resistance. Further, the base metal layer BSM can receive a voltage smaller than or equal to a threshold to detect the operation characteristics of the fourth test transistor TTR4.

A second buffer layer BUF2 and a first gate insulation film GI1 can be sequentially stacked to cover the base metal layer BSM.

A first lower gate electrode BG1 can be formed on the first gate insulation film GI1. The first lower gate electrode BG1 can be formed in the same layer as the first gate electrode GE1 using a gate metal material for forming the first gate electrode GE1 in the display area DA.

A first interlayer insulation film ILD1 can be formed on the first lower gate electrode BG1 to cover the first gate insulation film GI1.

A second lower gate electrode BG2 can be formed on the first interlayer insulation film ILD1. The second lower gate electrode BG2 can be formed in the same layer as the second gate electrode GE2 using a gate metal material for forming the second gate electrode GE2 in the display area DA.

The first lower gate electrode BG1 and the second lower gate electrode BG2 can be formed at positions that do not overlap each other.

A third buffer layer BUF3 can be formed on the second lower gate electrode BG2.

A third lower gate electrode BG3 can be formed on the third buffer layer BUF3. The third lower gate electrode BG3 can be formed in the same layer as the third gate electrode GE3 using a gate metal material for forming the third gate electrode GE3 in the display area DA.

A fourth buffer layer BUF4 can be formed on the third lower gate electrode BG3 to cover the third buffer layer BUF3.

A plurality of upper gate electrodes TG are formed on the second gate insulation film GI2. The upper gate electrode TG can include a first upper gate electrode TG1 having a first upper gate width, a second upper gate electrode TG2 having a second upper gate width, and a third upper gate electrode TG3 having a third upper gate width. The first upper gate width, the second upper gate width, and the third upper gate width can be different.

The first upper gate electrode TG1 can be disposed to at least partially overlap with the first lower gate electrode BG1, the second upper gate electrode TG2 can be disposed to at least partially overlap with the second lower gate electrode BG2, and the third upper gate electrode TG3 can be disposed to at least partially overlap with the third lower gate electrode BG3.

The first upper gate width can correspond to the channel width of the driving transistor constituting the red subpixel constituting the subpixel circuit, the second upper gate width can correspond to the channel width of the driving transistor constituting the green subpixel, and the third upper gate width can correspond to the channel width of the driving transistor constituting the blue subpixel.

Therefore, the fourth test transistor TTR4 can detect the operation characteristic of the driving transistor constituting the red subpixel by selecting the first upper gate electrode TG1 and the first lower gate electrode BG1.

Further, the fourth test transistor TTR4 can detect the operation characteristic of the driving transistor constituting the green subpixel by selecting the second upper gate electrode TG2 and the second lower gate electrode BG2.

Further, the fourth test transistor TTR4 can detect the operation characteristic of the driving transistor constituting the blue subpixel by selecting the third upper gate electrode TG3 and the third lower gate electrode BG3.

A second interlayer insulation film ILD2 can be formed on the upper gate electrode TG.

A contact hole can be formed so that a portion of the first lower gate electrode BG1 is exposed by etching a portion of the second interlayer insulation film ILD2, the fourth gate buffer layer BUF4, the third buffer layer BUF3, and the first interlayer insulation film ILD1, and a first connection line CL1 contacting the first lower gate electrode BG1 through the contact hole can be formed.

A contact hole can be formed so that a portion of the base metal layer BSM is exposed by etching a portion of the second interlayer insulation film ILD2, the fourth buffer layer BUF4, the third buffer layer BUF3, the first interlayer insulation film ILD1, the first gate insulation film GI1, and the second buffer layer BUF2. Therefore, the first lower gate electrode BG1 and the base metal layer BSM can be electrically connected by a first connection line CL1 formed through the contact hole.

Further, a contact hole can be formed so that a portion of the second lower gate electrode BG2 is exposed by etching a portion of the second interlayer insulation film ILD2, the fourth buffer layer BUF4, and the third buffer layer BUF3, and a second connection line CL2 contacting the second lower gate electrode BG2 through the contact hole can be formed.

A contact hole can be formed so that a portion of the base metal layer BSM is exposed by etching a portion of the second interlayer insulation film ILD2, the fourth buffer layer BUF4, the third buffer layer BUF3, the first interlayer insulation film ILD1, the first gate insulation film GI1, and the second buffer layer BUF2. Therefore, the second lower gate electrode BG2 and the base metal layer BSM can be electrically connected by a second connection line CL2 formed through the contact hole.

As a result, the resistance of the lower gate electrodes BG1 and BG2 of the fourth test transistor TTR4 is decreased, so that the operation characteristics of the fourth test transistor TTR4 can be effectively detected.

As such, the display device 100 of the disclosure can effectively analyze the operation characteristics of transistors of different structures constituting the subpixel circuit by disposing test transistors TTR including a plurality of upper gate electrodes and a plurality of lower gate electrodes in the non-display area NDA.

A display device and a display panel according to embodiments of the disclosure can be described as follows.

A display device can include a display panel including a display area where a subpixel is disposed and a non-display area where an image is not displayed outside the display area, and a driving circuit driving the display panel. The non-display area can include a first test transistor selectively detecting an operation characteristic of a transistor having a different size among a plurality of subpixel transistors constituting a subpixel circuit, and a second test transistor selectively detecting an operation characteristic of a transistor having a different position of a gate electrode among the plurality of subpixel transistors.

The first test transistor can include a base metal layer, a first insulation layer formed on an upper portion of the base metal layer, a lower gate electrode formed on an upper portion of the first insulation layer, a second insulation layer formed on an upper portion of the lower gate electrode, a plurality of upper gate electrodes formed on an upper portion of the second insulation layer, and a connection line electrically connecting the lower gate electrode and the base metal layer.

The base metal layer can be formed of the same material as an electrode of a capacitor constituting the subpixel circuit.

The lower gate electrode can be formed of the same material as a lower gate material of an oxide driving transistor constituting the subpixel circuit.

The upper gate electrode can be formed of the same material as an upper gate material of an oxide driving transistor constituting the subpixel circuit.

The upper gate electrode can include a first upper gate electrode having a first upper gate width, and a second upper gate electrode having a second upper gate width different from the first upper gate width.

The first upper gate electrode and the second upper gate electrode can be formed at positions overlapping the lower gate electrode.

The display device can detect an operation characteristic by selecting the first upper gate electrode and the lower gate electrode, or detect an operation characteristic by selecting the second upper gate electrode and the lower gate electrode.

The second test transistor can include a base metal layer, a first insulation layer formed on an upper portion of the base metal layer, a first lower gate electrode formed on an upper portion of the first insulation layer, a second insulation layer formed on an upper portion of the first lower gate electrode, a second lower gate electrode formed on an upper portion of the second insulation layer, a third insulation layer formed on an upper portion of the second lower gate electrode, an upper gate electrode formed on an upper portion of the third insulation layer, a first connection line electrically connecting the first lower gate electrode and the base metal layer, and a second connection line electrically connecting the second lower gate electrode and the base metal layer.

The base metal layer can be formed of the same material as an electrode of a capacitor constituting the subpixel circuit.

The first lower gate electrode and the second lower gate electrode can be formed of the same material as a lower gate material of an oxide transistor constituting the subpixel circuit.

The upper gate electrode can be formed of the same material as an upper gate material of an oxide driving transistor constituting the subpixel circuit.

The upper gate electrode can be formed at a position overlapping the first lower gate electrode and the second lower gate electrode.

The display device can detect an operation characteristic by selecting the upper gate electrode and the first lower gate electrode, or detect an operation characteristic by selecting the upper gate electrode and the second lower gate electrode.

The first test transistor can be disposed in a first test area, and the second test transistor can be disposed in a second test area spaced apart from the first test area.

The display device can further comprise a third test transistor selectively detecting an operation characteristic of a transistor having a different size and an operation characteristic of a transistor having a different gate electrode position among the plurality of subpixel transistors constituting the subpixel circuit.

The third test transistor can be positioned at a position spaced apart from the first test transistor and the second test transistor.

The third test transistor can include a base metal layer, a first insulation layer formed on an upper portion of the base metal layer, a first lower gate electrode formed on an upper portion of the first insulation layer, a second insulation layer formed on an upper portion of the first lower gate electrode, a second lower gate electrode formed on an upper portion of the second insulation layer, a third insulation layer formed on an upper portion of the second lower gate electrode, a plurality of upper gate electrode formed on an upper portion of the third insulation layer, a first connection line electrically connecting the first lower gate electrode and the base metal layer, and a second connection line electrically connecting the second lower gate electrode and the base metal layer.

The base metal layer can be formed of the same material as an electrode of a capacitor constituting the subpixel circuit.

The first lower gate electrode and the second lower gate electrode can be formed of the same material as a lower gate material of an oxide transistor constituting the subpixel circuit.

The upper gate electrode can include a first upper gate electrode having a first upper gate width, and a second upper gate electrode having a second upper gate width different from the first upper gate width.

The first upper gate electrode can be formed at a position overlapping the first lower gate electrode and the second lower gate electrode.

The display device can detect an operation characteristic by selecting the first upper gate electrode and the first lower gate electrode, detect an operation characteristic by selecting the first upper gate electrode and the second lower gate electrode, or detect an operation characteristic by selecting the second upper gate electrode and the second lower gate electrode.

The display device can further comprise a fourth test transistor selectively detecting an operation characteristic of three or more transistors having different sizes and gate electrode positions among the plurality of subpixel transistors constituting the subpixel circuit.

The fourth test transistor can include a base metal layer, a first insulation layer formed on an upper portion of the base metal layer, a first lower gate electrode formed on an upper portion of the first insulation layer, a second insulation layer formed on an upper portion of the first lower gate electrode, a second lower gate electrode formed on an upper portion of the second insulation layer, a third insulation layer formed on an upper portion of the second lower gate electrode, a third lower gate electrode formed on an upper portion of the third insulation layer, a fourth insulation layer formed on an upper portion of the third lower gate electrode, an upper gate electrode formed on an upper portion of the fourth insulation layer and including a first upper gate electrode, a second upper gate electrode, and a third upper gate electrode, a first connection line electrically connecting the first lower gate electrode and the base metal layer, and a second connection line electrically connecting the second lower gate electrode and the base metal layer.

The first upper gate electrode can be formed with a first upper gate width, the second upper gate electrode can be formed with a second upper gate width different from the first upper gate width, and the third upper gate electrode can be formed with a third upper gate width different from the first upper gate width and the second upper gate width.

The first upper gate electrode can be formed at a position overlapping the first lower gate electrode, the second upper gate electrode can be formed at a position overlapping the second lower gate electrode, and the third upper gate electrode can be formed at a position overlapping the third lower gate electrode.

The display device can detect an operation characteristic by selecting the first upper gate electrode and the first lower gate electrode, detect an operation characteristic by selecting the second upper gate electrode and the second lower gate electrode, or detect an operation characteristic by selecting the third upper gate electrode and the third lower gate electrode.

A display panel according to the disclosure can include a display area where a subpixel is disposed, and a non-display area where an image is not displayed outside the display area. The non-display area can include a first test area where a first test transistor is disposed, the first test transistor selectively detecting an operation characteristic of a transistor having a different channel layer size among a plurality of subpixel transistors constituting a subpixel circuit, and a second test area where a second test transistor is disposed, the second test transistor selectively detecting an operation characteristic of a transistor having a different gate electrode position among the plurality of subpixel transistors.

The display panel can further include a third test area where a third test transistor is disposed selectively detecting an operation characteristic of a transistor having a different size and an operation characteristic of a transistor having a different gate electrode position among the plurality of subpixel transistors constituting the subpixel circuit.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a display panel including a display area having a subpixel and a non-display area outside of the display area; and
a driving circuit configured to drive the display panel,
wherein the non-display area includes:
a first test transistor configured to selectively detect an operation characteristic of a transistor having a different size among a plurality of subpixel transistors included in a subpixel circuit; and
a second test transistor configured to selectively detect an operation characteristic of a transistor having a different position of a gate electrode among the plurality of subpixel transistors included in the subpixel circuit.

2. The display device of claim 1, wherein the first test transistor includes:
a base metal layer;
a first insulation layer disposed on an upper portion of the base metal layer;
a lower gate electrode disposed on an upper portion of the first insulation layer;
a second insulation layer disposed on an upper portion of the lower gate electrode;
a plurality of upper gate electrodes disposed on an upper portion of the second insulation layer; and
a connection line electrically connecting the lower gate electrode and the base metal layer.

3. The display device of claim 2, wherein the base metal layer includes a same material as an electrode of a capacitor included in the subpixel circuit.

4. The display device of claim 2, wherein the lower gate electrode includes a same material as a lower gate material of an oxide driving transistor included in the subpixel circuit.

5. The display device of claim 2, wherein each of the plurality of upper gate electrodes includes a same material as an upper gate material of an oxide driving transistor constituting the subpixel circuit.

6. The display device of claim 2, wherein the plurality of upper gate electrodes include:
a first upper gate electrode having a first upper gate width; and
a second upper gate electrode having a second upper gate width different from the first upper gate width, and
wherein the first upper gate electrode and the second upper gate electrode overlap with the lower gate electrode.

7. The display device of claim 6, wherein the first test transistor is configured to detect an operation characteristic by selecting the first upper gate electrode and the lower gate electrode, or an operation characteristic by selecting the second upper gate electrode and the lower gate electrode.

8. The display device of claim 1, wherein the second test transistor includes:
a base metal layer;
a first insulation layer disposed on an upper portion of the base metal layer;
a first lower gate electrode disposed on an upper portion of the first insulation layer;
a second insulation layer disposed on an upper portion of the first lower gate electrode;
a second lower gate electrode disposed on an upper portion of the second insulation layer;
a third insulation layer disposed on an upper portion of the second lower gate electrode;
an upper gate electrode disposed on an upper portion of the third insulation layer;
a first connection line electrically connecting the first lower gate electrode and the base metal layer; and
a second connection line electrically connecting the second lower gate electrode and the base metal layer.

9. The display device of claim 8, wherein the base metal layer includes a same material as an electrode of a capacitor included in the subpixel circuit.

10. The display device of claim 8, wherein the first lower gate electrode and the second lower gate electrode include a same material as a lower gate material of an oxide transistor included in the subpixel circuit.

11. The display device of claim 8, wherein the first lower gate electrode and the second lower gate electrode include a same material as a gate material of a silicon transistor included in the subpixel circuit.

12. The display device of claim 8, wherein the upper gate electrode includes a same material as an upper gate material of an oxide driving transistor included in the subpixel circuit, and the upper gate electrode overlaps with the first lower gate electrode and the second lower gate electrode.

13. The display device of claim 8, wherein the upper gate electrode includes:
a first upper gate electrode disposed on an upper portion of the third insulation layer; and
a second upper gate electrode disposed on the upper portion of the third insulation layer and spaced apart from the first upper gate electrode.

14. The display device of claim 13, wherein the first upper gate electrode has a first upper gate width, and the second upper gate electrode has a second upper gate width different from the first upper gate width, and
wherein the first upper gate electrode overlaps with the first lower gate electrode and the second lower gate electrode.

15. The display device of claim 1, further comprising a third test transistor configured to selectively detect an operation characteristic of a transistor having a different channel layer size and an operation characteristic of a transistor having a different gate electrode position among the plurality of subpixel transistors included in the subpixel circuit.

16. The display device of claim 15, wherein the first test transistor is disposed in a first test area of the non-display area,
wherein the second test transistor is disposed in a second test area in the non-display area and spaced apart from the first test area, and
wherein the third test transistor is disposed in a third test area in the non-display area and spaced apart from the first test area and the second test area.

17. The display device of claim 15, wherein the third test transistor includes:
a base metal layer;
a first insulation layer disposed on an upper portion of the base metal layer;
a first lower gate electrode disposed on an upper portion of the first insulation layer;
a second insulation layer disposed on an upper portion of the first lower gate electrode;
a second lower gate electrode disposed on an upper portion of the second insulation layer;
a third insulation layer disposed on an upper portion of the second lower gate electrode;
a plurality of upper gate electrodes disposed on an upper portion of the third insulation layer;
a first connection line electrically connecting the first lower gate electrode and the base metal layer; and
a second connection line electrically connecting the second lower gate electrode and the base metal layer.

18. The display device of claim 1, further comprising a fourth test transistor configured to selectively detect an operation characteristic of three or more transistors having different channel layer sizes and different gate electrode positions among the plurality of subpixel transistors included in the subpixel circuit.

19. The display device of claim 18, wherein the fourth test transistor includes:
a base metal layer;
a first insulation layer disposed on an upper portion of the base metal layer;
a first lower gate electrode disposed on an upper portion of the first insulation layer;
a second insulation layer disposed on an upper portion of the first lower gate electrode;
a second lower gate electrode disposed on an upper portion of the second insulation layer;
a third insulation layer disposed on an upper portion of the second lower gate electrode;
a third lower gate electrode disposed on an upper portion of the third insulation layer;
a fourth insulation layer disposed on an upper portion of the third lower gate electrode;
an upper gate electrode disposed on an upper portion of the fourth insulation layer and including a first upper gate electrode, a second upper gate electrode, and a third upper gate electrode;
a first connection line electrically connecting the first lower gate electrode and the base metal layer; and
a second connection line electrically connecting the second lower gate electrode and the base metal layer.

20. The display device of claim 19, wherein the first upper gate electrode has a first upper gate width,
wherein the second upper gate electrode has a second upper gate width different from the first upper gate width, and
wherein the third upper gate electrode has a third upper gate width different from the first upper gate width and the second upper gate width,
wherein the first upper gate electrode overlaps with the first lower gate electrode,
wherein the second upper gate electrode overlaps with the second lower gate electrode, and
wherein the third upper gate electrode overlaps with the third lower gate electrode.

21. A display panel, comprising:
a display area including a subpixel; and
a non-display area outside of the display area, wherein the non-display area includes:
a first test area including a first test transistor, the first test transistor being configured to selectively detect an operation characteristic of a transistor having a different channel layer size among a plurality of subpixel transistors constituting a subpixel circuit; and
a second test area including a second test transistor, the second test transistor being configured to selectively detect an operation characteristic of a transistor having a different gate electrode position among the plurality of subpixel transistors.

22. A display panel comprising:
a plurality of subpixels configured to display an image; and
a test transistor configured to detect operation characteristics of at least two different transistors included in a same subpixel circuit corresponding to one of the plurality of subpixels,
wherein the at least two different transistors have different structures.

23. The display panel of claim 22, wherein the test transistor includes:
a first upper gate electrode;
a second upper gate electrode; and
a lower gate electrode,
wherein the first upper gate electrode and the second upper gate electrode overlap with the lower gate electrode.

24. The display panel of claim 23, wherein the test transistor is configured to:
detect a first operation characteristic of a first transistor included in the same subpixel circuit having a first channel width corresponding to a width of the first upper gate electrode by selecting the first upper gate electrode and the lower gate electrode, and
detect a second operation characteristic of a second transistor included in the same subpixel circuit having a second channel width corresponding to a width of the second upper gate electrode by selecting the second upper gate electrode and the lower gate electrode,
wherein the first channel width is different than the second channel width.

25. The display panel of claim 22, wherein the test transistor includes:
a first lower gate electrode;
a second lower gate electrode; and
an upper gate electrode,
wherein the upper gate electrode overlaps with a part of the first lower gate electrode and a part of the second lower gate electrode.

26. The display panel of claim 25, wherein the test transistor is configured to:
detect a first operation characteristic of a first transistor included in the same subpixel by selecting the first lower gate electrode and the upper gate electrode, and
detect a second operation characteristic of a second transistor included in the same subpixel circuit by selecting the second lower gate electrode and the upper gate electrode,
wherein the first transistor and the second transistor have lower gate electrodes disposed on different layers within the same subpixel circuit.
